(19) United States
(12) Patent Application Publication
(10) Pub. No.: US 2025/0351415 A1
(43) Pub. Date: Nov. 13, 2025

(54) SEMICONDUCTOR DEVICE

(71) Applicant: Samsung Electronics Co., Ltd., Suwon-si (KR)

(72) Inventors: Hyunggoo LEE, Suwon-si (KR); Gwanho KIM, Suwon-si (KR); Ki-Il KIM, Suwon-si (KR); Hyonwook RA, Suwon-si (KR); JeongDo YOO, Suwon-si (KR)

(73) Assignee: Samsung Electronics Co., Ltd., Suwon-si (KR)

(21) Appl. No.: 18/967,425

(22) Filed: Dec. 3, 2024

(30) Foreign Application Priority Data
May 9, 2024 (KR) 10-2024-0061125

(51) Int. Cl. H10D 30/00; H10D 30/01

(52) U.S. Cl. CPC H10D 30/502; H10D 30/0191; H10D 30/0198

(57) ABSTRACT

A semiconductor device may include a substrate including an active pattern, a lower power line in a lower portion of the substrate, a channel pattern on the active pattern and including a plurality of semiconductor patterns, which are stacked and include a first semiconductor pattern at the lowermost level, a gate electrode crossing the active pattern and including a first inner gate electrode between the active pattern and the first semiconductor pattern, source/drain patterns on the substrate, backside contacts connecting the lower power line to the source/drain patterns, and a filler structure between adjacent backside contacts among the backside contacts. The filler structure may include a filling pattern and a liner. The filling pattern may include a contact portion on a filler portion, and the liner may cover opposite side surfaces of the filler portion. The contact portion may be in direct contact with the substrate.

### CROSS-REFERENCE TO RELATED APPLICATIONS

This U.S. non-provisional patent application claims priority under 35 U.S.C. § 119 to Korean Patent Application No. 10-2024-0061125, filed on May 9, 2024, in the Korean Intellectual Property Office, the entire contents of which are hereby incorporated by reference.

### BACKGROUND

The present disclosure relates to semiconductor devices and methods of fabricating the same, and in particular, to semiconductor devices including field effect transistors and methods of fabricating the same.

A semiconductor device may include an integrated circuit having metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize high-performance semiconductor devices.

### SUMMARY

An embodiment of inventive concepts provides a semiconductor device with improved electrical and reliability characteristics.

An embodiment of inventive concepts provides a method of fabricating a semiconductor device with improved electrical and reliability characteristics.

According to an embodiment of inventive concepts, a semiconductor device may include a substrate including an active pattern; a lower power line in a lower portion of the substrate; a channel pattern on the active pattern, the channel pattern including a plurality of semiconductor patterns, the plurality of semiconductor patterns being stacked and spaced apart from each other, and a lowermost level of the plurality of semiconductor patterns including a first semiconductor pattern; a gate electrode crossing the active pattern, the gate electrode including a first inner gate electrode between the active pattern and the first semiconductor pattern; source/drain patterns on the substrate; backside contacts connecting the lower power line to the source/drain patterns; and a filler structure between adjacent backside contacts among the backside contacts. The filler structure may include a filling pattern and a liner. The filling pattern may include a filler portion and a contact portion on the filler portion. The liner may cover opposite side surfaces of the filler portion. The contact portion may be in direct contact with the substrate.

According to an embodiment of inventive concepts, a semiconductor device may include a substrate including an active pattern; a lower power line in a lower portion of the substrate; a channel pattern on the active pattern, the channel pattern including a plurality of semiconductor patterns, the plurality of semiconductor patterns being stacked and spaced apart from each other, and a lowermost level of the plurality of semiconductor patterns including a first semiconductor pattern; a gate electrode crossing the active pattern, the gate electrode including a first inner gate electrode between the active pattern and the first semiconductor pattern; source/drain patterns on the substrate; backside contacts connecting the lower power line to the source/drain patterns; and a filler structure between adjacent backside contacts among the backside contacts. The filler structure may include a filling pattern and a liner. The filling pattern may include a filler portion and a contact portion on the filler portion. The liner may cover opposite side surfaces of the filler portion. A topmost portion of the liner may be lower than a topmost portion of the contact portion.

According to an embodiment of inventive concepts, a semiconductor device may include a substrate including an active pattern; channel patterns on the active pattern, the channel patterns including a plurality of semiconductor patterns, the plurality of semiconductor patterns being stacked and spaced apart from each other, the plurality of semiconductor patterns including a first semiconductor pattern; source/drain patterns connected to the channel patterns; a gate electrode on the channel patterns, the gate electrode including a first inner gate electrode between the active pattern and first semiconductor pattern; a gate insulating layer between the gate electrode and the channel patterns; a gate spacer on a side surface of the gate electrode; a gate capping pattern on a top surface of the gate electrode; an interlayer insulating layer covering the source/drain pattern and the gate capping pattern; a gate contact penetrating the interlayer insulating layer and the gate capping pattern, the gate contact being electrically connected to the gate electrode; a first metal layer on the interlayer insulating layer, the first metal layer include a first interconnection line electrically connected to the gate contact; a lower power line in a lower portion of the substrate; backside contacts penetrating the substrate and electrically connecting the lower power line to the source/drain pattern; and a filler structure between adjacent backside contacts among the backside contacts. The filler structure may include a filling pattern and a liner. The filling pattern may include a filler portion and a contact portion on the filler portion. The liner may cover opposite side surfaces of the filler portion. As a distance from a bottom surface of the filling pattern increases in a vertical direction, a width of the filling pattern may decrease and then may increase at a boundary between the filler portion and the contact portion.

### BRIEF DESCRIPTION OF THE DRAWINGS

FIGS. 1 to 3 are conceptual diagrams illustrating logic cells of a semiconductor device according to an embodiment of inventive concepts.

FIG. 4 is a plan view illustrating a semiconductor device according to an embodiment of inventive concepts.

FIGS. 5A to 5D are sectional views taken along lines A-A′, B-B′, C-C′, and D-D′ of FIG. 4, respectively.

FIG. 6A is an enlarged sectional view illustrating a portion ‘M’ of FIG. 5A.

FIG. 6B is an enlarged sectional view illustrating a portion ‘M’ of FIG. 5A, according to another embodiment of inventive concepts.

FIGS. 7A to 21B are sectional views illustrating a method of fabricating a semiconductor device, according to an embodiment of inventive concepts.

### DETAILED DESCRIPTION

Example embodiments of inventive concepts will now be described more fully with reference to the accompanying drawings, in which example embodiments are shown.

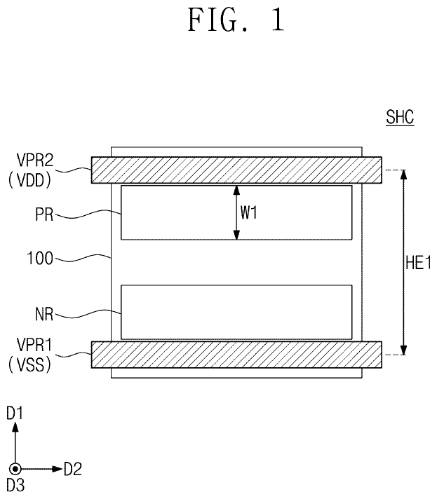

FIGS. 1 to 3 are conceptual diagrams illustrating logic cells of a semiconductor device according to an embodiment of inventive concepts.

Referring to FIG. 1, a single height cell SHC may be provided. In detail, a first lower power line VPR1 and a second lower power line VPR2 may be provided below a substrate 100. The first lower power line VPR1 may be a conduction path, to which a source voltage VSS (e.g., a ground voltage) is provided. The second lower power line VPR2 may be a conduction path, to which a drain voltage VDD (e.g., a power voltage) is provided.

The single height cell SHC may be defined between the first lower power line VPR1 and the second lower power line VPR2. The single height cell SHC may include one PMOSFET region PR and one NMOSFET region NR. In other words, the single height cell SHC may have a CMOS structure provided between the first lower power line VPR1 and the second lower power line VPR2.

Each of the PMOSFET and NMOSFET regions PR and NR may have a first width in a first direction D1. A length of the single height cell SHC in the first direction D1 may be defined as a first height HE1. The first height HE1 may be substantially equal to a distance (e.g., pitch) between the first lower power line VPR1 and the second lower power line VPR2.

The single height cell SHC may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

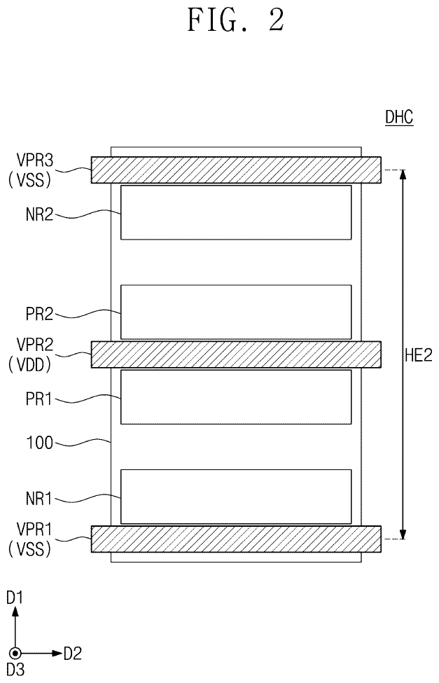

Referring to FIG. 2, a double height cell DHC may be provided. In detail, the first lower power line VPR1, the second lower power line VPR2, and a third lower power line VPR3 may be provided on the substrate 100. The second lower power line VPR2 may be disposed between the first lower power line VPR1 and the third lower power line VPR3. The third lower power line VPR3 may be a conduction path, to which the source voltage VSS is provided.

The double height cell DHC may be defined between the first lower power line VPR1 and the third lower power line VPR3. The double height cell DHC may include a first PMOSFET region PR1, a second PMOSFET region PR2, a first NMOSFET region NR1, and a second NMOSFET region NR2.

The first NMOSFET region NR1 may be adjacent to the first lower power line VPR1. The second NMOSFET region NR2 may be adjacent to the third lower power line VPR3. The first and second PMOSFET regions PR1 and PR2 may be adjacent to the second lower power line VPR2. When viewed in a plan view, the second lower power line VPR2 may be disposed between the first and second PMOSFET regions PR1 and PR2.

A length of the double height cell DHC in the first direction D1 may be defined as a second height HE2. The second height HE2 may be about two times the first height HE1 of FIG. 1. The first and second PMOSFET regions PR1 and PR2 of the double height cell DHC may be combined to serve as a single PMOSFET region. Thus, a channel size of the PMOS transistor of the double height cell DHC may be larger than a channel size of the PMOS transistor of the single height cell SHC of FIG. 1.

For example, the channel size of the PMOS transistor of the double height cell DHC may be about two times the channel size of the PMOS transistor of the single height cell SHC. In this case, the double height cell DHC may be operated at a higher speed than the single height cell SHC. In an embodiment, the double height cell DHC shown in FIG. 2 may be defined as a multi-height cell. In an embodiment, the multi-height cell may include a triple height cell whose cell height is about three times that of the single height cell SHC.

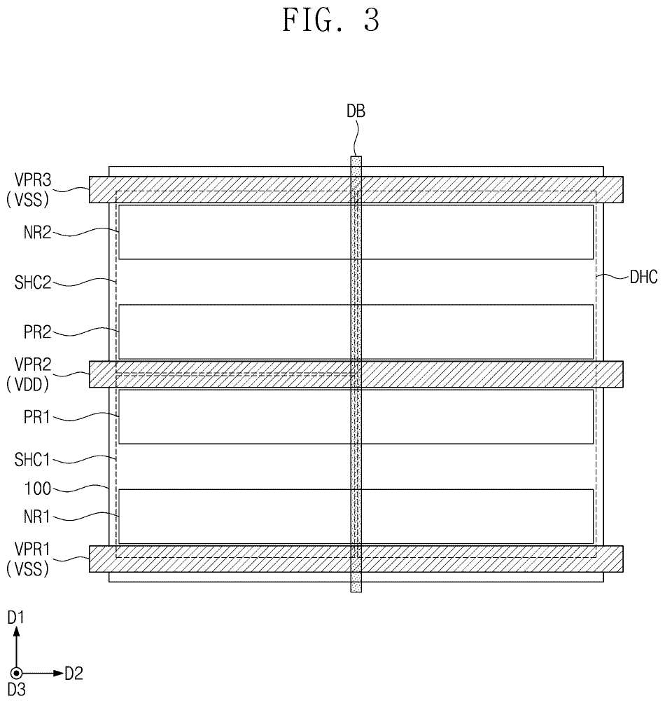

Referring to FIG. 3, a first single height cell SHC1, a second single height cell SHC2, and a double height cell DHC may be two-dimensionally arranged on the substrate 100. The first single height cell SHC1 may be disposed between the first and second lower power lines VPR1 and VPR2. The second single height cell SHC2 may be disposed between the second and third lower power lines VPR2 and VPR3. The second single height cell SHC2 may be adjacent to the first single height cell SHC1 in the first direction D1.

The double height cell DHC may be disposed between the first and third lower power lines VPR1 and VPR3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. An active region of the double height cell DHC may be electrically separated from an active region of each of the first and second single height cells SHC1 and SHC2 by the division structure DB.

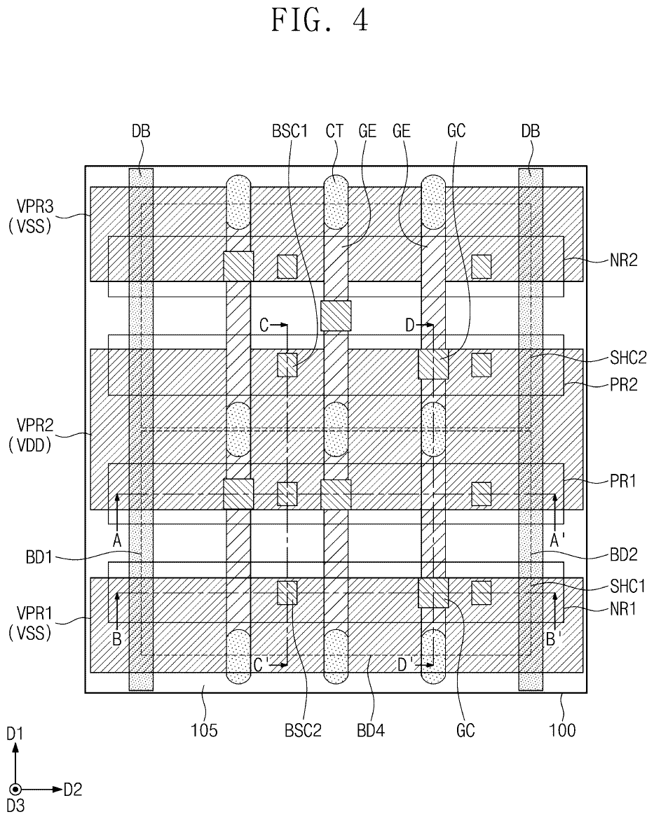

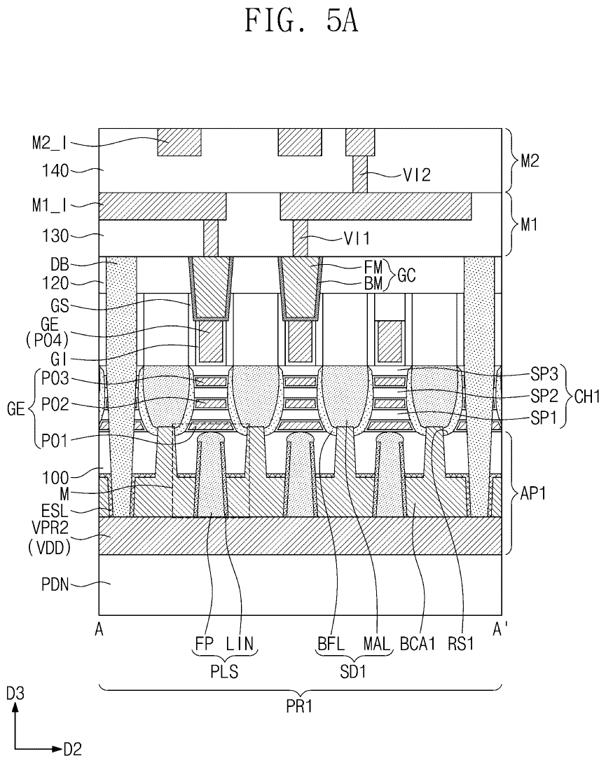

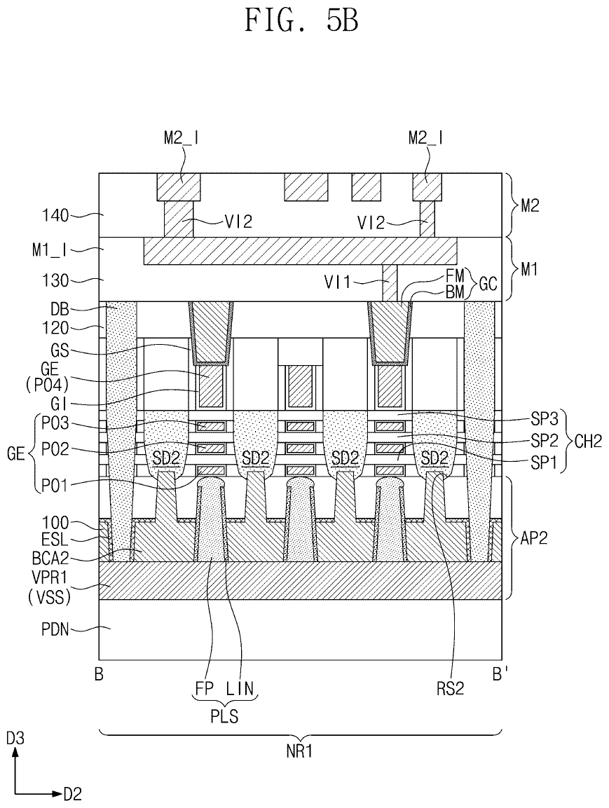

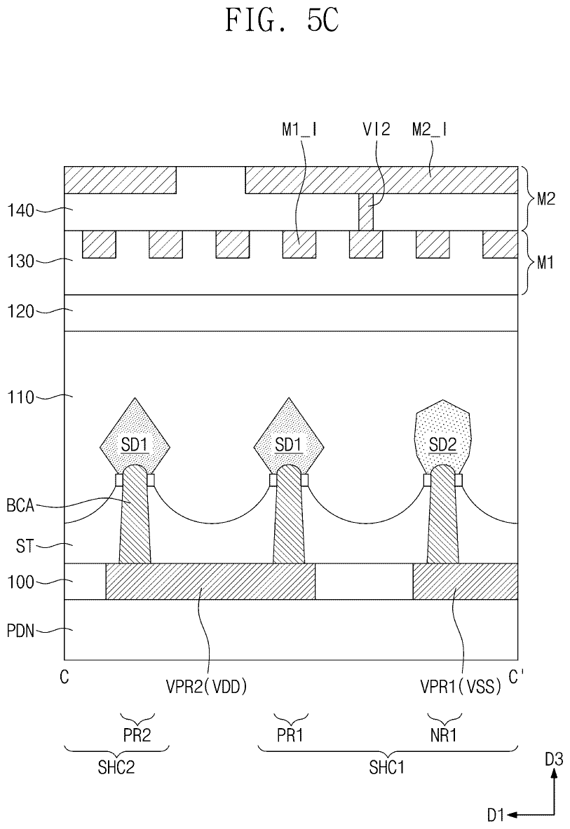

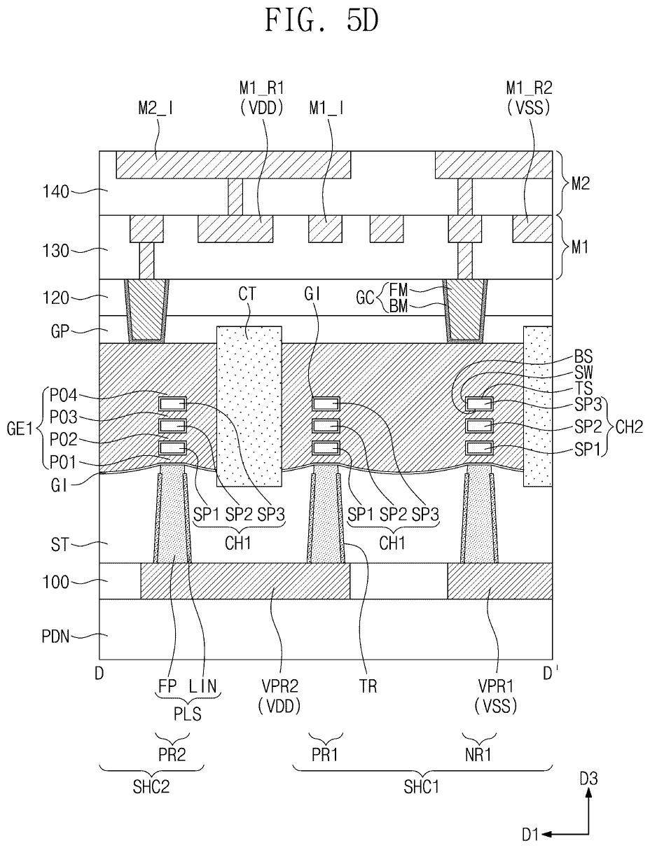

FIG. 4 is a plan view illustrating a semiconductor device according to an embodiment of inventive concepts. FIGS. 5A to 5D are sectional views taken along lines A-A′, B-B′, C-C′, and D-D′ of FIG. 4, respectively. FIGS. 4 and 5A to 5E illustrate a detailed structure of the first and second single height cells SHC1 and SHC2 of FIG. 3.

Referring to FIG. 4 and FIGS. 5A to 5D, the first and second single height cells SHC1 and SHC2 may be provided on the substrate 100. Logic transistors constituting a logic circuit may be disposed on each of the first and second single height cells SHC1 and SHC2. The substrate 100 may be a semiconductor substrate that is formed of or includes silicon, germanium, silicon germanium, a compound semiconductor material, or the like. As an example, the substrate 100 may be a silicon substrate. Lower power lines VPR1 to VPR3, which will be described below, may be disposed in the substrate 100.

The substrate 100 may include the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may be extended in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR, which is formed in an upper portion of the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may be extended in the second direction D2. Each of the first and second active patterns AP1 and AP2 may be a vertically protruding portion of the substrate 100.

A device isolation layer ST may fill the trench TR. The device isolation layer ST may cover a side surface of each of the first and second active patterns AP1 and AP2. The device isolation layer ST may include a silicon oxide layer. The device isolation layer ST may not cover first and second channel patterns CH1 and CH2, which will be described below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may be formed of or include silicon (Si), germanium (Ge), or silicon germanium (SiGe). For example, each of the first to third semiconductor patterns SP1, SP2, and SP3 may be formed of or include crystalline silicon. In an embodiment, each of the first to third semiconductor patterns SP1, SP2, and SP3 may be a nanosheet.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between a pair of the first source/drain patterns SD1. That is, each pair of the first source/drain patterns SD1 may be connected to each other by the first to third semiconductor patterns SP1, SP2, and SP3 stacked.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., n-type). The second channel pattern CH2 may be interposed between each pair of the second source/drain patterns SD2. In other words, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. In an embodiment, each of the first and second source/drain patterns SD1 and SD2 may have a top surface that is located at substantially the same level as a top surface of the third semiconductor pattern SP3. In another embodiment, the top surface of each of the first and second source/drain patterns SD1 and SD2 may be higher than the top surface of the third semiconductor pattern SP3.

The first source/drain patterns SD1 may be formed of or include a semiconductor material (e.g., SiGe) whose lattice constant is greater than that of the first channel pattern CH1. In this case, the pair of the first source/drain patterns SD1 may exert a compressive stress on the first channel patterns CH1 therebetween. The second source/drain patterns SD2 may be formed of or include the same semiconductor element (e.g., Si) as the second channel pattern CH2.

Each of the first source/drain patterns SD1 may include a buffer layer BFL and a main layer MAL on the buffer layer BFL. Referring back to FIG. 5A, the buffer layer BFL may cover an inner surface of the first recess RS1. The main layer MAL may fill an unfilled region of the first recess RS1 covered with the buffer layer BFL. The main layer MAL may have a volume that is greater than that of the buffer layer BFL. Each of the buffer and main layers BFL and MAL may be formed of or include silicon germanium (SiGe). In detail, the buffer layer BFL may contain a relatively low concentration of germanium (Ge). In another embodiment, the buffer layer BFL may contain only silicon (Si), without germanium (Ge). A germanium concentration of the buffer layer BFL may range from 0 at % to 30 at %.

The main layer MAL may contain a relatively high concentration of germanium. In an embodiment, the germanium concentration of the main layer MAL may range from 30 at % to 70 at %. The germanium concentration of the main layer MAL may increase in the third direction D3. For example, a portion of the main layer MAL, which is adjacent to the buffer layer BFL, may have a germanium concentration of about 40 at %, and an upper portion of the main layer MAL may have a germanium concentration of about 60 at %.

Each of the buffer and main layers BFL and MAL may contain an impurity (e.g., boron, gallium, or indium) that allows the first source/drain pattern SD1 to have a p-type conductivity. The impurity concentration of each of the buffer and main layers BFL and MAL may range from 1E18 atoms/cm³ to 5E22 atoms/cm³. The impurity concentration of the main layer MAL may be higher than the impurity concentration of the buffer layer BFL.

The buffer layer BFL may be used to protect the main layer MAL in a process of replacing second semiconductor layers SAL with first to third inner electrodes PO1, PO2, and PO3 of a gate electrode GE, as will be described below. In other words, the buffer layer BFL may limit and/or prevent an etchant material, which is used to remove the second semiconductor layers SAL, from entering and etching the main layer MAL.

Each of the second source/drain patterns SD2 may be formed of or include silicon (Si). The second source/drain pattern SD2 may further contain impurities (e.g., phosphorus, arsenic, or antimony) that allow the second source/drain pattern SD2 to have an n-type conductivity. The impurity concentration of the second source/drain pattern SD2 may range from 1E18 atoms/cm³ to 5E22 atoms/cm³.

Gate electrodes GE may be provided to cross the first and second channel patterns CH1 and CH2 and to extend in the first direction D1. The gate electrodes GE may be arranged at a first pitch in the second direction D2. Each of the gate electrodes GE may be vertically overlapped with the first and second channel patterns CH1 and CH2.

The gate electrode GE may include a first inner electrode PO1 interposed between the first and second active patterns AP1 and AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 5D, the gate electrode GE may be provided on a top surface TS, a bottom surface BS, and opposite side surfaces SW of each of the first to third semiconductor patterns SP1, SP2, and SP3. That is, the transistor according to the present embodiment may be a three-dimensional field effect transistor (e.g., MBCFET or GAAFET) in which the gate electrode GE is provided to three-dimensionally surround the channel pattern.

As an example, the first single height cell SHC1 may have a first border BD1 and a second border BD2, which are opposite to each other in the second direction D2. The first and second borders BD1 and BD2 may be extended in the first direction D1. The first single height cell SHC1 may have a third border BD3 and a fourth border BD4, which are opposite to each other in the first direction D1. The third and fourth borders BD3 and BD4 may be extended in the second direction D2.

Gate cutting patterns CT may be disposed on borders, which are parallel to the second direction D2, of each of the first and second single height cells SHC1 and SHC2. For example, the gate cutting patterns CT may be disposed on the third and fourth borders BD3 and BD4 of the first single height cell SHC1. The gate cutting patterns CT may be arranged at the first pitch along the third border BD3. The gate cutting patterns CT may be arranged at the first pitch along the fourth border BD4. When viewed in a plan view, the gate cutting patterns CT on the third and fourth borders BD3 and BD4 may be disposed to be overlapped with the gate electrodes GE, respectively. The gate cutting patterns CT may be formed of or include at least one of insulating materials (e.g., silicon oxide, silicon nitride, or combinations thereof).

The gate electrode GE on the first single height cell SHC1 may be separated from the gate electrode GE on the second single height cell SHC2 by the gate cutting pattern CT. The gate cutting pattern CT may be interposed between the gate electrodes GE, which are placed on the first and second single height cells SHC1 and SHC2 aligned to each other in the first direction D1. That is, the gate electrode GE extending in the first direction D1 may be divided into a plurality of the gate electrodes GE by the gate cutting patterns CT.

Referring back to FIG. 4 and FIGS. 5A to 5D, a pair of gate spacers GS may be respectively disposed on opposite side surfaces of the outer electrode PO4 of the gate electrode GE. The gate spacers GS may be extended along the gate electrode GE and in the first direction D1. Top surfaces of the gate spacers GS may be higher than a top surface of the gate electrode GE. The top surfaces of the gate spacers GS may be substantially coplanar with a top surface of a first interlayer insulating layer 110, which will be described below. The gate spacers GS may be formed of or include at least one of SiCN, SiCON, or SiN. In an embodiment, the gate spacers GS may be a multi-layered structure, which includes at least two different materials selected from SiCN, SiCON, and SiN.

A gate capping pattern GP may be provided on the gate electrode GE. The gate capping pattern GP may be extended along the gate electrode GE or in the first direction D1. The gate capping pattern GP may be formed of or include a material having an etch selectivity with respect to first and second interlayer insulating layers 110 and 120, which will be described below. In detail, the gate capping pattern GP may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and the opposite side surfaces SW of each of the first to third semiconductor patterns SP1, SP2, and SP3. The gate insulating layer GI may cover a top surface of the device isolation layer ST below the gate electrode GE. The gate insulating layer GI may be interposed between the first inner electrode PO1 and the first and second active patterns AP1 and AP2.

In an embodiment, the gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first to third inner electrodes PO1, PO2, and PO3 of the gate electrode GE may be composed of the first metal pattern or the work-function metal.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In an embodiment, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may include at least one metallic material, which is selected from the group consisting of tungsten (W), aluminum (Al), titanium (Ti), and tantalum (Ta). In an embodiment, the outer electrode PO4 of the gate electrode GE may include the first metal pattern and the second metal pattern on the first metal pattern.

A first interlayer insulating layer 110 may be provided on the substrate 100. The first interlayer insulating layer 110 may cover the gate spacers GS and the first and second source/drain patterns SD1 and SD2. A top surface of the first interlayer insulating layer 110 may be substantially coplanar with a top surface of the gate capping pattern GP and a top surface of the gate spacer GS. A second interlayer insulating layer 120 may be formed on the first interlayer insulating layer 110 to cover the gate capping pattern GP. A third interlayer insulating layer 130 may be provided on the second interlayer insulating layer 120. A fourth interlayer insulating layer 140 may be provided on the third interlayer insulating layer 130. In an embodiment, each of the first to fourth interlayer insulating layers 110-140 may include a silicon oxide layer.

A pair of division structures DB, which are opposite to each other in the second direction D2, may be provided at both sides of each of the first and second single height cells SHC1 and SHC2. For example, a pair of the division structures DB may be respectively provided on the first and second borders BD1 and BD2 of the first single height cell SHC1. The division structure DB may be extended in the first direction D1 to be parallel to the gate electrodes GE.

The division structure DB may be provided to penetrate the gate capping pattern GP and the gate electrode GE and may be extended into the first and second active patterns AP1 and AP2. The division structure DB may be provided to penetrate an upper portion of each of the first and second active patterns AP1 and AP2. The division structure DB may electrically separate an active region of each of the first and second single height cells SHC1 and SHC2 from an active region of a neighboring cell.

Gate contacts GC may be provided to penetrate the second interlayer insulating layer 120 and the gate capping pattern GP and may be electrically connected to the gate electrodes GE, respectively. When viewed in a plan view, two gate contacts GC on the first single height cell SHC1 may be disposed to be overlapped with the first PMOSFET region PR1. That is, the two gate contacts GC on the first single height cell SHC1 may be provided on the first active pattern AP1 (e.g., see FIG. 5A). When viewed in a plan view, one gate contact GC on the first single height cell SHC1 may be disposed to be overlapped with the first NMOSFET region NR1. In other words, the one gate contact GC on the first single height cell SHC1 may be provided on the second active pattern AP2 (e.g., see FIG. 5B).

The gate contact GC may be freely disposed on the gate electrode GE, without any restrictions on its position. For example, the gate contacts GC on the second single height cell SHC2 may be respectively disposed on the second PMOSFET region PR2, the second NMOSFET region NR2, and the device isolation layer ST filling the trench TR (e.g., see FIG. 4).

The gate contact GC may include a conductive pattern FM and a barrier pattern BM enclosing the conductive pattern FM. For example, the conductive pattern FM may be formed of or include at least one of metallic materials (e.g., aluminum, copper, tungsten, molybdenum, and cobalt). The barrier pattern BM may be provided to cover side and bottom surfaces of the conductive pattern FM. In an embodiment, the barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CoN), or platinum nitride (PtN).

Referring back to FIGS. 4 and 5C to 5D, first to third lower power lines VPR1, VPR2, and VPR3 may be provided in a lower portion of the substrate 100. The first to third lower power lines VPR1, VPR2, and VPR3 may be extended in the second direction D2 to be parallel to each other. The first lower power line VPR1 may be disposed on the fourth border BD4 of the first single height cell SHC1. The second lower power line VPR2 may be disposed on the third border BD3 of the first single height cell SHC1. In other words, the first single height cell SHC1 may be defined between the first lower power line VPR1 and the second lower power line VPR2. The second single height cell SHC2 may be defined between the second lower power line VPR2 and the third lower power line VPR3.

In an embodiment, the first lower power line VPR1 may be vertically overlapped with the first NMOSFET region NR1. The second lower power line VPR2 may be vertically overlapped with the first PMOSFET region PR1 and the second PMOSFET region PR2. The third lower power line VPR3 may be vertically overlapped with the second NMOSFET region NR2.

The first to third lower power lines VPR1 to VPR3 may be formed of or include at least one selected from the group consisting of copper, molybdenum, tungsten, and ruthenium. A bottom surface of each of the first to third lower power lines VPR1 to VPR3 may be coplanar with a bottom surface of the substrate 100.

A power delivery network layer PDN may be provided on the bottom surface of the substrate 100. The power delivery network layer PDN may include a plurality of lower interconnection lines, which are electrically connected to the first to third lower power lines VPR1 to VPR3. As an example, the power delivery network layer PDN may include a wiring network, which is used to apply the source voltage VSS to the first and third lower power lines VPR1 and VPR3. The power delivery network layer PDN may include a wiring network, which is used to apply the drain voltage VDD to the second lower power line VPR2.

Referring back to FIGS. 4, 5A, 5B, and 5D, a first backside contact BCA1 may be provided to vertically extend from the second lower power line VPR2 to the first source/drain pattern SD1 through the substrate 100. A second backside contact BCA2 may be provided to vertically extend from the first lower power line VPR1 to the second source/drain pattern SD2 through the substrate 100. A width of the first and second backside contacts BCA1 and BCA2 in the second direction D2 may decrease as a distance from the bottom surface of the substrate 100 increases in the vertical direction D3.

The first backside contact BCA1 may vertically and electrically connect the second lower power line VPR2 to the first source/drain pattern SD1. The drain voltage VDD may be applied to the first source/drain pattern SD1 through the first backside contact BCA1.

The second backside contact BCA2 may vertically and electrically connect the first lower power line VPR1 to the second source/drain pattern SD2. The source voltage VSS may be applied to the second source/drain pattern SD2 through the second backside contact BCA2.

Each of the first and second backside contacts BCA1 and BCA2 may include a body portion and a protruding portion on the body portion. The body portion may be buried in the substrate 100 and may be electrically connected to the lower power line VPR1, VPR2, or VPR3 to be described below. The protruding portion may be a conductive pillar-shaped structure that is provided to penetrate the substrate 100 and is vertically and electrically connected to the first or second source/drain pattern SD1 or SD2.

An etch stop layer ESL may be provided between the body portions of the first and second backside contacts BCA1 and BCA2 and the substrate 100. The etch stop layer ESL may be formed of or include a different material from the substrate 100.

A filler structure PLS may be interposed between adjacent ones of the first backside contacts BCA1. The filler structure PLS may be interposed between adjacent ones of the second backside contacts BCA2. The filler structure PLS may be provided to penetrate the substrate 100 and the etch stop layer ESL. An upper portion of the filler structure PLS may be in contact with the gate electrode GE or the gate insulating layer GI. The filler structure PLS may have a pillar shape.

As a distance from a bottom surface of the filler structure PLS increases in the vertical direction D3, a width of the filler structure PLS may decrease, but inventive concepts are not limited to this example. The filler structure PLS may be used to electrically separate adjacent ones of the first backside contacts BCA1 from each other. The filler structure PLS may be used to electrically separate adjacent ones of the second backside contacts BCA2 from each other.

Referring back to FIG. 4 and FIGS. 5A to 5D, a first metal layer M1 may be provided in the third interlayer insulating layer 130. The first metal layer M1 may include first interconnection lines M1_I. The first interconnection lines M1_I of the first metal layer M1 may be extended in the second direction D2 to be parallel to each other.

According to an embodiment of inventive concepts, a power line, which is used to supply a power to the single height cell SHC, may be provided in the form of the lower power line VPR1-VPR3 and may be buried in the substrate 100. Thus, the power line may be omitted from the first metal layer M1. The first interconnection lines M1_I, which are used for signal transmission, may be disposed in the first metal layer M1.

The first metal layer M1 may further include first vias VI1. The first vias VI1 may be respectively provided below the first interconnection lines M1_I of the first metal layer M1. The first interconnection line M1_I of the first metal layer M1 may be electrically connected to the gate contact GC through the first via VI1.

The first interconnection line M1_I of the first metal layer M1 and the first via VI1 thereunder may be separately formed by different processes. That is, each of the first interconnection line M1_I and the first via VI1 of the first metal layer M1 may be formed by a single damascene process. The semiconductor device according to the present embodiment may be fabricated using a sub-20 nm process.

A second metal layer M2 may be provided in the fourth interlayer insulating layer 140. The second metal layer M2 may include a plurality of second interconnection lines M2_I. Each of the second interconnection lines M2_I of the second metal layer M2 may be a line- or bar-shaped pattern that is extended in the first direction D1. In other words, the second interconnection lines M2_I may be extended in the first direction D1 to be parallel to each other.

The second metal layer M2 may further include second vias VI2, which are respectively provided below the second interconnection lines M2_I. The first interconnection line M1_I of the first metal layer M1 and the second interconnection line M2_I of the second metal layer M2 may be electrically connected to each other through the second via VI2. As an example, the second interconnection line M2_I of the second metal layer M2 and the second via VI2 thereunder may be formed by a dual damascene process.

The first interconnection line M1_I of the first metal layer M1 and the second interconnection line M2_I of the second metal layer M2 may be formed of or include the same conductive material or different conductive materials. For example, the first interconnection line M1_I of the first metal layer M1 and the second interconnection line M2_I of the second metal layer M2 may be formed of or include at least one of metallic materials (e.g., aluminum, copper, tungsten, molybdenum, ruthenium, and cobalt). Although not shown, a plurality of metal layers (e.g., M3, M4, M5, and so forth) may be additionally stacked on the fourth interlayer insulating layer 140. Each of the stacked metal layers may include interconnection lines, which are used as routing paths between cells.

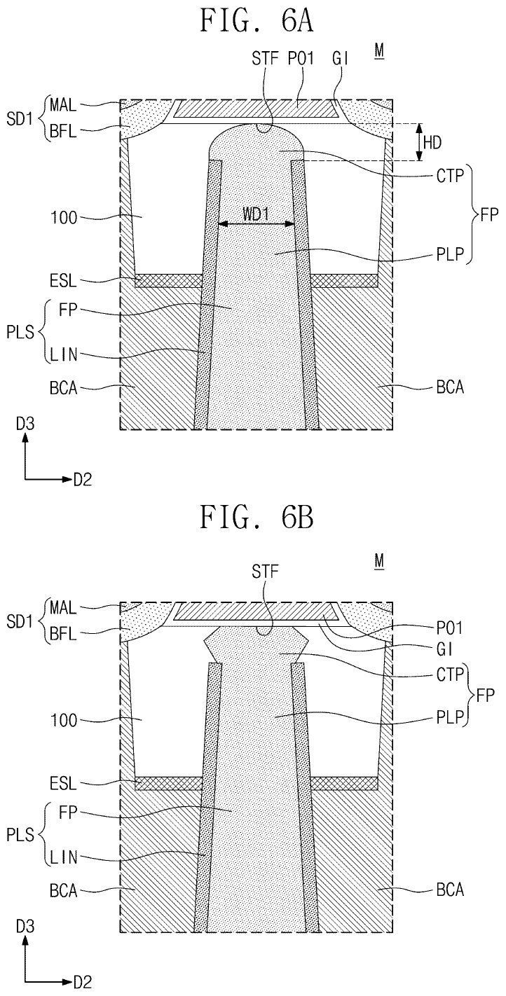

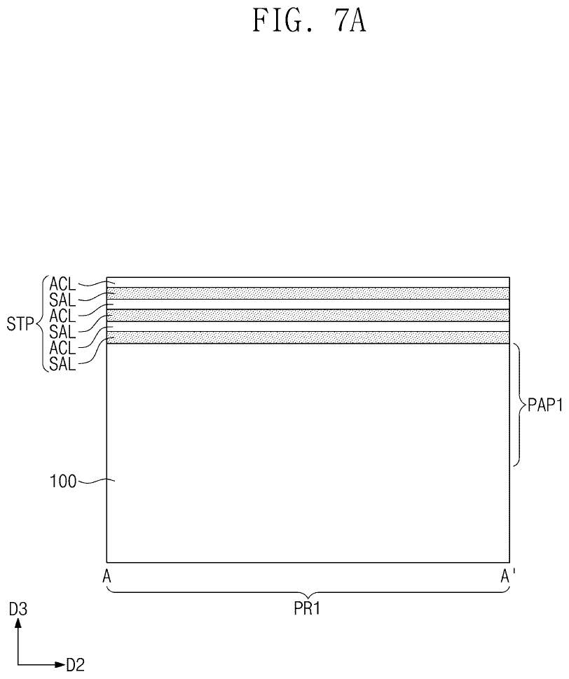

FIG. 6A is an enlarged sectional view illustrating a portion ‘M’ of FIG. 5A. The filler structure PLS will be described in more detail with reference to FIG. 6A.

Referring to FIGS. 6A and 6B, the filler structure PLS may include a filling pattern FP and a liner LIN. The filling pattern FP may include a filler portion PLP and a contact portion CTP on the filler portion PLP. The filler portion PLP may be a portion of the filling pattern FP that is extended from the bottom surface of the filler structure PLS in the vertical direction D3. The contact portion CTP may be an upper portion of the filling pattern FP. The contact portion CTP may be a portion of the filling pattern FP that is adjacent to the gate electrode GE or the gate insulating layer GI. The contact portion CTP may have an elliptical profile.

At least a portion of the contact portion CTP may be in direct contact with the gate insulating layer GI interposed between the first inner electrode PO1 and the substrate 100. In an embodiment, a top surface STF of the contact portion CTP may be in direct contact with the gate insulating layer GI.

The liner LIN may be provided on opposite side surfaces of the filler portion PLP. The liner LIN may cover the opposite side surfaces of the filler portion PLP. The liner LIN may not cover the side surfaces of the contact portion CTP. The liner LIN may be omitted from a region between the contact portion CTP and the substrate 100. Thus, the contact portion CTP may be in direct contact with the substrate 100. The topmost portion of the liner LIN may be located at a level that is lower than the topmost portion of the contact portion CTP. The top surface STF of the contact portion CTP may be higher than a top surface of the liner LIN. A height difference HD between the top surface STF of the contact portion CTP and the top surface of the liner LIN may range from 1 nm to 5 nm.

The liner LIN may be interposed between the filler portion PLP and the substrate 100 and between the filler portion PLP and the first and second backside contacts BCA1 and BCA2. The liner LIN may be interposed between the filler portion PLP and the device isolation layer ST.

The filling pattern FP may include an insulating material. For example, the filling pattern FP may include a silicon oxide layer. The filling pattern FP and the liner LIN may be formed of or include different materials from each other. The liner LIN may include a material having an etch selectivity with respect to the substrate 100. The liner LIN may include a material having an etch selectivity with respect to silicon (Si). For example, the liner LIN may include a silicon-based insulating material (e.g., SiO, SiN, SiOC, or SiOCN).

As a distance from a bottom surface of the filling pattern FP increases in a vertical direction, a width WD1 of the filling pattern FP may decrease and then may increase at a border between the filler and contact portions PLP and CTP. An upper portion of the filler portion PLP may have a width that is smaller than a lower portion of the contact portion CTP. This is because the liner LIN is omitted from the side surfaces of the contact portion CTP. As a distance from the bottom surface of the filling pattern FP increases in a vertical direction, a width of the filler portion PLP may decrease. A width of the liner LIN may be smaller than a width of the filling pattern FP.

FIG. 6B is an enlarged sectional view illustrating a portion ‘M’ of FIG. 5A, according to an embodiment of inventive concepts. In the following description, an element previously described with reference to FIG. 6A may be identified by the same reference number without repeating an overlapping description thereof, for concise description.

Referring to FIG. 6B, the contact portion CTP may be provided to have a polygonal section. For example, the contact portion CTP may have a Sigma profile. A side surface of the contact portion CTP may include a first surface and a second surface. The first surface may have a first slope, and the second surface may have a second slope. One of the first and second slopes may be a positive slope, and the other may be a negative slope. The first and second surfaces may meet each other and may define a vertex of the contact portion CTP. As a distance from the filler portion PLP increases, a width of the contact portion CTP may increase, reach a maximum value, and then decrease again.

According to an embodiment of inventive concepts, the filler structure PLS may be provided between the first and second backside contacts BCA1 and BCA2 to be in contact with the gate insulating layer GI. The filler structure PLS may be used to electrically separate adjacent ones of the first and second backside contacts BCA1 and BCA2 from each other. The filler structure PLS may include the filling pattern FP and the liner LIN, and here, the liner LIN may be provided to cover the side surfaces of the filler portion PLP of the filling pattern FP. The liner LIN may be omitted from the contact portion CTP of the filling pattern FP, and thus, the contact portion CTP of the filling pattern FP may be in direct contact with the substrate 100. This is because, in a fabrication process to be described below, the filler structure PLS is formed through two separate etching processes. As a result, the reliability and electrical characteristics of the semiconductor device may be improved.

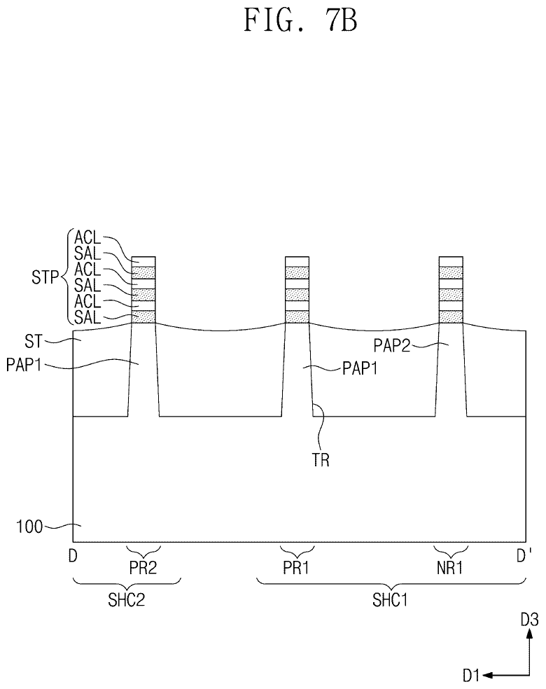

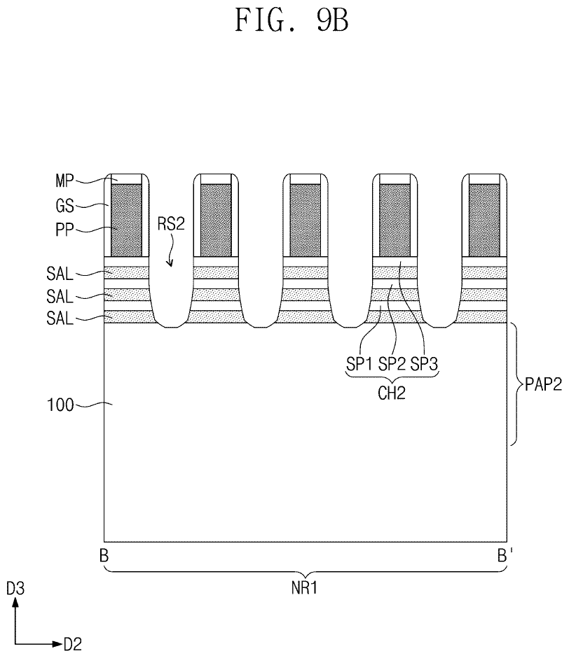

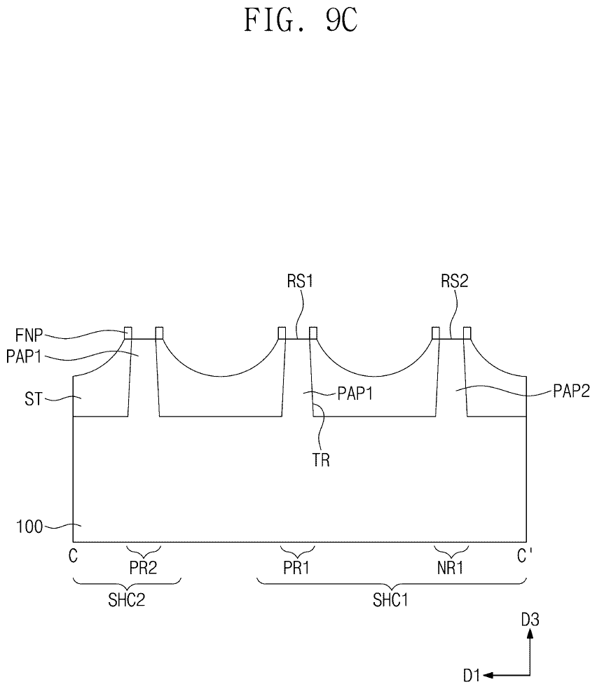

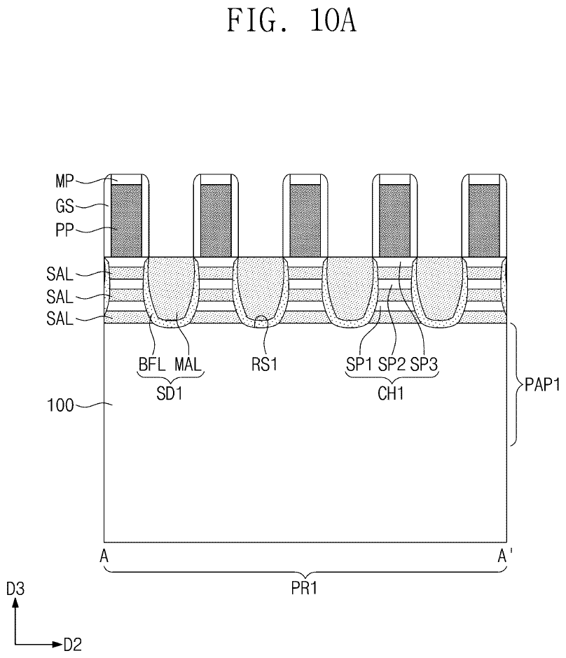

FIGS. 7A to 21B are sectional views illustrating a method of fabricating a semiconductor device, according to an embodiment of inventive concepts. In detail, FIGS. 7A, 8A, 9A, 10A, 11A, 12A, 13A, 14, 15, 16, 17, 18, 19, 20, and 21A are sectional views corresponding to the line A-A′ of FIG. 4. FIGS. 9B, 10B, 11B, and 12B are sectional views corresponding to the line B-B′ of FIG. 4. FIGS. 9C, 10C, 12C, 13B, and 21B are sectional views corresponding to the line C-C′ of FIG. 4. FIGS. 7B, 8B, 11C, and 12D are sectional views corresponding to the line D-D′ of FIG. 4.

Referring to FIGS. 7A and 7B, the substrate 100 including the first and second PMOSFET regions PR1 and PR2 and the first and second NMOSFET regions NR1 and NR2 may be provided. For example, the substrate 100 may be a silicon wafer.

First and second semiconductor layers ACL and SAL, which are alternately stacked on the substrate 100, may be formed. Each of the first and second semiconductor layers ACL and SAL may be formed of or include at least one of silicon (Si), germanium (Ge), or silicon-germanium (SiGe), but the first and second semiconductor layers ACL and SAL may be formed of different materials from each other.

The second semiconductor layer SAL may be formed of or include a material that is chosen to have an etch selectivity with respect to the first semiconductor layer ACL. For example, the first semiconductor layers ACL may be formed of or include silicon (Si), and the second semiconductor layers SAL may be formed of or include silicon-germanium (SiGe). A germanium concentration of each of the second semiconductor layers SAL may range from 10 at % to 35 at %.

Mask patterns may be respectively formed on the first and second PMOSFET regions PR1 and PR2 and the first and second NMOSFET regions NR1 and NR2 of the substrate 100. The mask pattern may be a line- or bar-shaped pattern that is extended in the second direction D2.

A patterning process using the mask patterns as an etch mask may be performed to form the trench TR defining a first preliminary active pattern PAP1 and a second preliminary active pattern PAP2. The first preliminary active pattern PAP1 may be formed on each of the first and second PMOSFET regions PR1 and PR2. The second preliminary active pattern PAP2 may be formed on each of the first and second NMOSFET regions NR1 and NR2. When viewed in a plan view, the first and second preliminary active patterns PAP1 and PAP2 may be line-shaped patterns that are extended in the second direction D2 and are parallel to each other.

A stacking pattern STP may be formed on each of the first and second preliminary active patterns PAP1 and PAP2. The stacking pattern STP may include the first semiconductor layers ACL and the second semiconductor layers SAL, which are alternatingly stacked on the first and second preliminary active patterns PAP1 and PAP2. During the patterning process, the stacking pattern STP may be formed together with the first and second preliminary active patterns PAP1 and PAP2.

The device isolation layer ST may be formed to fill the trench TR. In detail, an insulating layer may be formed on the substrate 100 to cover the first and second preliminary active patterns PAP1 and PAP2 and the stacking patterns STP. The device isolation layer ST may be formed by recessing the insulating layer to expose the stacking patterns STP.

The device isolation layer ST may be formed of or include at least one of insulating materials (e.g., silicon oxide). The stacking patterns STP may be placed at a level higher than the device isolation layer ST and may be exposed to the outside of the device isolation layer ST. In other words, the stacking patterns STP may protrude vertically above the device isolation layer ST.

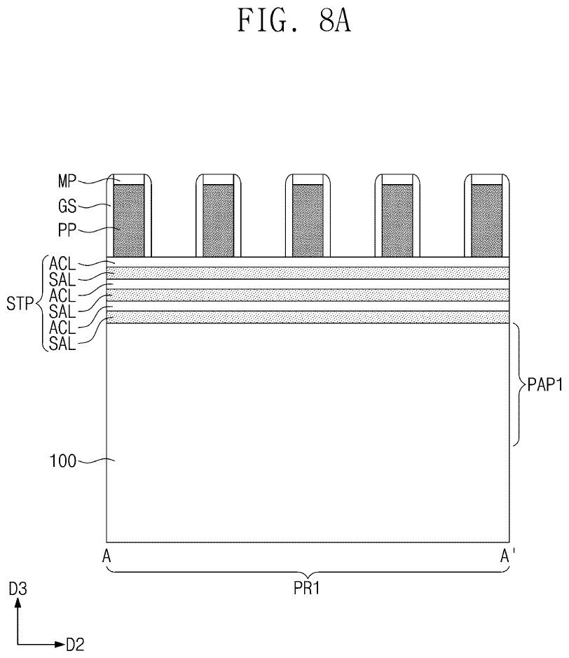

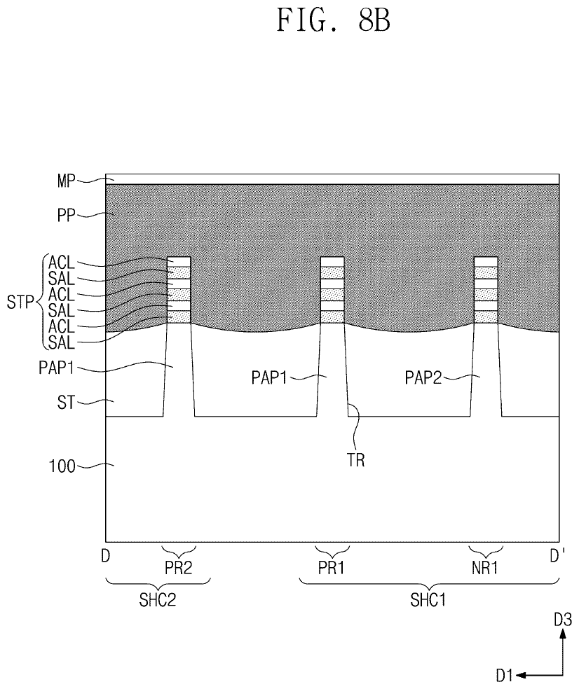

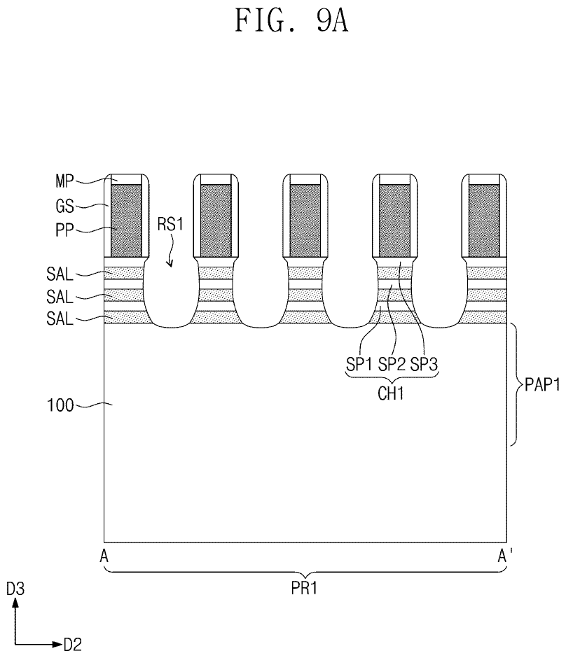

Referring to FIGS. 8A and 8B, sacrificial patterns PP may be formed on the substrate 100 to cross the stacking patterns STP. Each of the sacrificial patterns PP may be a line- or bar-shaped pattern that is extended in the first direction D1. The sacrificial patterns PP may be arranged at a first pitch in the second direction D2.

In detail, the formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may be formed of or include polysilicon.

A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. The gate spacer layer may be formed of or include at least one of SiCN, SiCON, or SiN. In an embodiment, the gate spacer layer may be a multi-layered structure including at least two of SiCN, SiCON, or SiN.

Referring to FIGS. 9A to 9C, the first recesses RS1 may be formed in the stacking pattern STP on the first preliminary active pattern PAP1. The second recesses RS2 may be formed in the stacking pattern STP on the second preliminary active pattern PAP2. During the formation of the first and second recesses RS1 and RS2, the device isolation layer ST may be further recessed at both sides of each of the first and second preliminary active patterns PAP1 and PAP2 (e.g., see FIG. 9C).

In detail, the first recesses RS1 may be formed by etching the stacking pattern STP on the first preliminary active pattern PAP1 using the hard mask patterns MP and the gate spacers GS as an etch mask. The first recess RS1 may be formed between a pair of the sacrificial patterns PP. The second recesses RS2 in the stacking pattern STP on the second preliminary active pattern PAP2 may be formed by the same method as that for the first recesses RS1.

Referring back to FIG. 9C, a fence pattern FNP may be formed on each of the first and second preliminary active patterns PAP1 and PAP2. The fence pattern FNP may be a remaining portion of the gate spacer GS.

Referring back to FIGS. 7A to 7C, the first to third semiconductor patterns SP1, SP2, and SP3, which are sequentially stacked between adjacent ones of the first recesses RS1, may be formed from the first semiconductor layers ACL, respectively. The first to third semiconductor patterns SP1, SP2, and SP3, which are sequentially stacked between adjacent ones of the second recesses RS2, may be formed from the first semiconductor layers ACL, respectively. The first to third semiconductor patterns SP1, SP2, and SP3 between adjacent ones of the first recesses RS1 may constitute the first channel pattern CH1. The first to third semiconductor patterns SP1, SP2, and SP3 between adjacent ones of the second recesses RS2 may constitute the second channel pattern CH2.

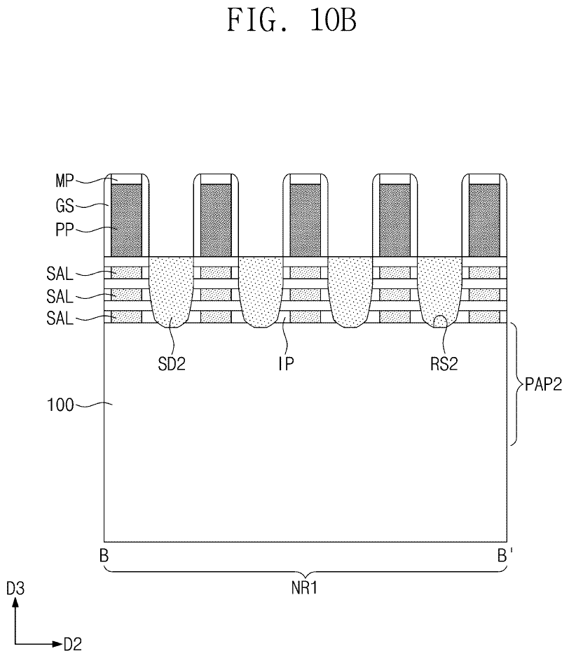

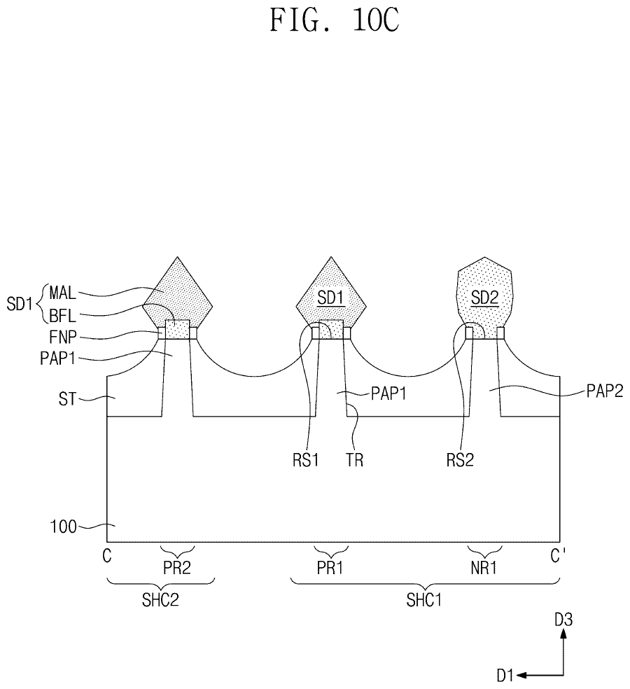

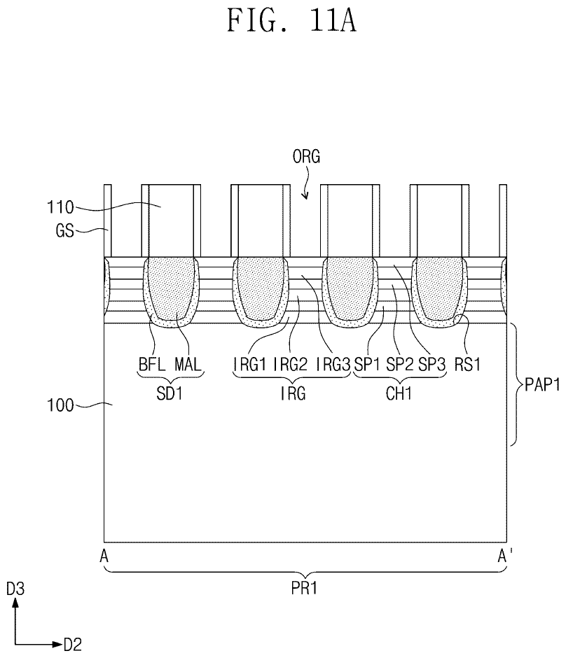

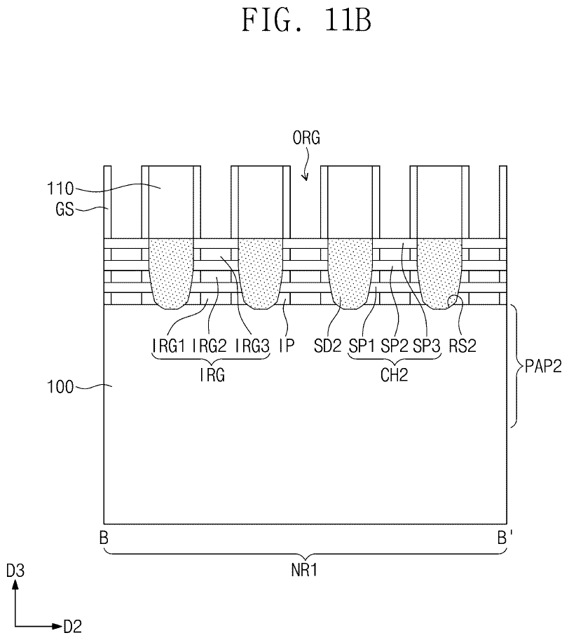

Referring to FIGS. 10A to 10C, the first source/drain patterns SD1 may be formed in the first recesses RS1, respectively. In detail, the buffer layer BFL may be formed by a first SEG process using an inner surface of the first recess RS1 as a seed layer. The buffer layer BFL may be grown using the first to third semiconductor patterns SP1, SP2, and SP3 and the substrate 100, which are exposed through the first recess RS1, as a seed layer. As an example, the first SEG process may include a chemical vapor deposition (CVD) process or a molecular beam epitaxy (MBE) process.

The buffer layer BFL may contain a semiconductor material (e.g., SiGe) whose lattice constant is larger than that of a semiconductor material of the substrate 100. The buffer layer BFL may contain a relatively low concentration of germanium (Ge). In another embodiment, the buffer layer BFL may contain only silicon (Si), without germanium (Ge). A germanium concentration of the buffer layer BFL may range from 0 at % to 30 at %.

A second SEG process may be performed on the buffer layer BFL to form the main layer MAL. The main layer MAL may be formed to fill the first recess RS1 completely or nearly completely. The main layer MAL may contain a relatively high concentration of germanium. In an embodiment, the germanium concentration of the main layer MAL may range from 30 at % to 70 at %.

The first source/drain pattern SD1 may be doped in-situ with p-type impurities (e.g., boron, gallium, or indium) during the formation of the buffer and main layers BFL and MAL. Alternatively, impurities may be injected into the first source/drain pattern SD1, after the formation of the first source/drain pattern SD1.

The second source/drain patterns SD2 may be formed in the second recesses RS2, respectively. In detail, the second source/drain pattern SD2 may be formed by a SEG process, in which an inner surface of the second recess RS2 is used as a seed layer. In an embodiment, the second source/drain pattern SD2 may be formed of or include the same semiconductor material (e.g., Si) as the substrate 100.

During the formation of the second source/drain pattern SD2, the second source/drain pattern SD2 may be doped in-situ with n-type impurities (e.g., phosphorus, arsenic, or antimony). Alternatively, impurities may be injected into the second source/drain pattern SD2, after the formation of the second source/drain pattern SD2.

In an embodiment, before the formation of the second source/drain pattern SD2, an inner spacer IP may be formed by replacing a portion of the second semiconductor layer SAL, which is exposed by the second recess RS2, with an insulating material. As a result, the inner spacers IP may be respectively formed between the second source/drain pattern SD2 and the second semiconductor layers SAL.

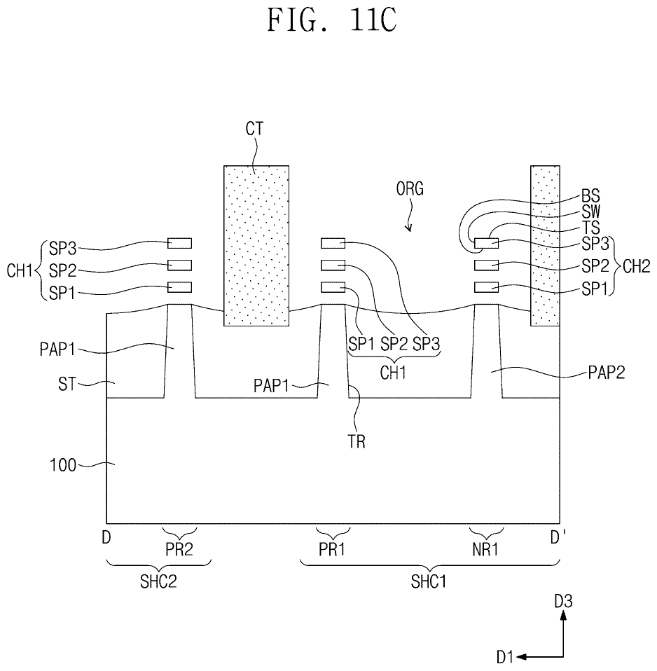

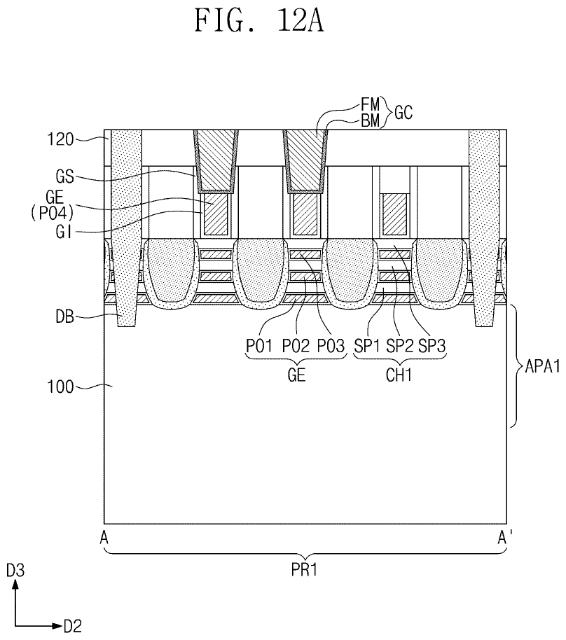

Referring to FIGS. 11A to 11C, the first interlayer insulating layer 110 may be formed to cover the first and second source/drain patterns SD1 and SD2, the hard mask patterns MP, and the gate spacers GS. In an embodiment, the first interlayer insulating layer 110 may include a silicon oxide layer.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. All the hard mask patterns MP may be removed during the planarization process. As a result, the first interlayer insulating layer 110 may be formed to have a top surface that is coplanar with the top surfaces of the sacrificial patterns PP and the top surfaces of the gate spacers GS.

A photolithography process may be performed to selectively open a region of the sacrificial pattern PP. For example, a region of the sacrificial pattern PP on the third and fourth borders BD3 and BD4 of the first single height cell SHC1 may be selectively opened. The opened region of the sacrificial pattern PP may be selectively etched and removed. The gate cutting pattern CT may be formed by filling a space, which is formed by removing the sacrificial pattern PP, with an insulating material (e.g., see FIG. 11C).

In an embodiment, the exposed sacrificial patterns PP may be selectively removed. As a result of the removal of the sacrificial patterns PP, an outer region ORG exposing the first and second channel patterns CH1 and CH2 may be formed (e.g., see FIG. 10C). The removal of the sacrificial patterns PP may include a wet etching process which is performed using an etching solution capable of selectively etching polysilicon.

The second semiconductor layers SAL, which are exposed through the outer region ORG, may be selectively removed to form inner regions IRG (e.g., see FIG. 11C). In detail, an etching process of selectively etching the second semiconductor layers SAL may be performed to leave the first to third semiconductor patterns SP1, SP2, and SP3 and to remove only the second semiconductor layers SAL. An etch recipe for the etching process may be chosen to etch a layer (e.g., a silicon germanium layer), which has a relatively high germanium concentration, at a high etch rate. For example, the etching process may be chosen to have a high etch rate to a silicon germanium layer whose germanium concentration is higher than 10 at %.

During the etching process, the second semiconductor layers SAL may be completely removed from the first and second PMOSFET regions PR1 and PR2 and the first and second NMOSFET regions NR1 and NR2. The etching process may be a wet etching process. An etchant material, which is used in the etching process, may be chosen to quickly remove the second semiconductor layer SAL having a relatively high germanium concentration. Meanwhile, the first source/drain patterns SD1 on the first and second PMOSFET regions PR1 and PR2 may be protected from the etching process by the buffer layer BFL having a relatively low germanium concentration.

Referring back to FIG. 11C, as a result of the selective removal of the second semiconductor layers SAL, only the first to third semiconductor patterns SP1, SP2, and SP3 stacked may be left on each of the first and second preliminary active patterns PAP1 and PAP2. Empty regions, which are formed by removing the second semiconductor layers SAL, may be used as first to third inner regions IRG1, IRG2, and IRG3, respectively. In detail, the first inner region IRG1 may be formed between the substrate 100 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

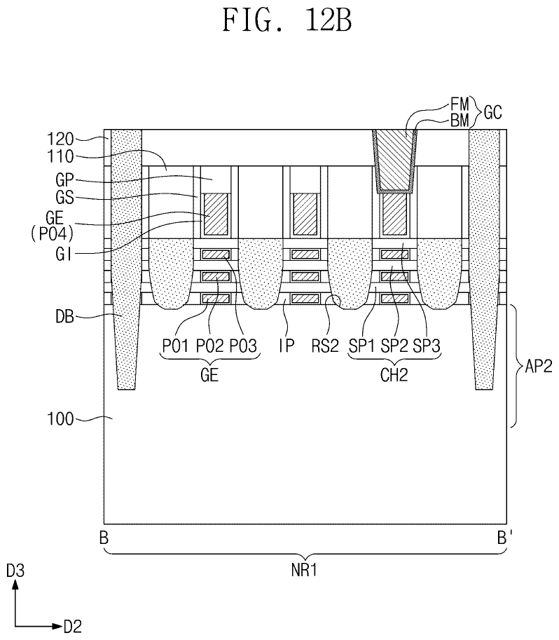

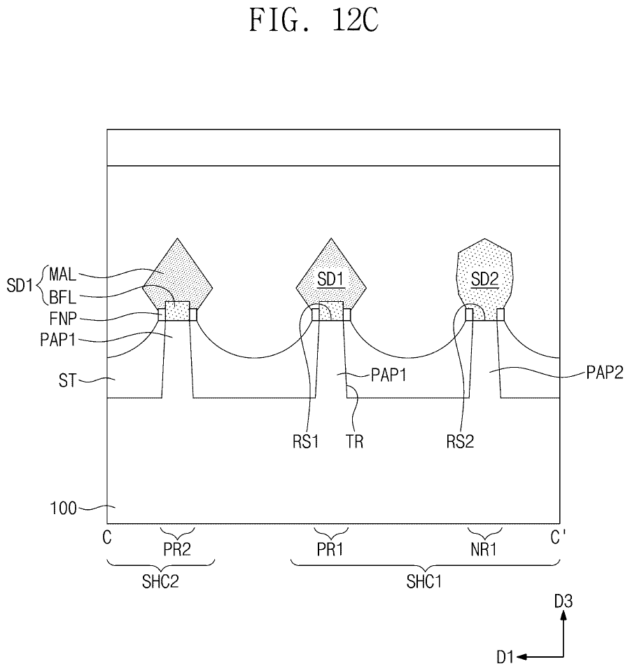

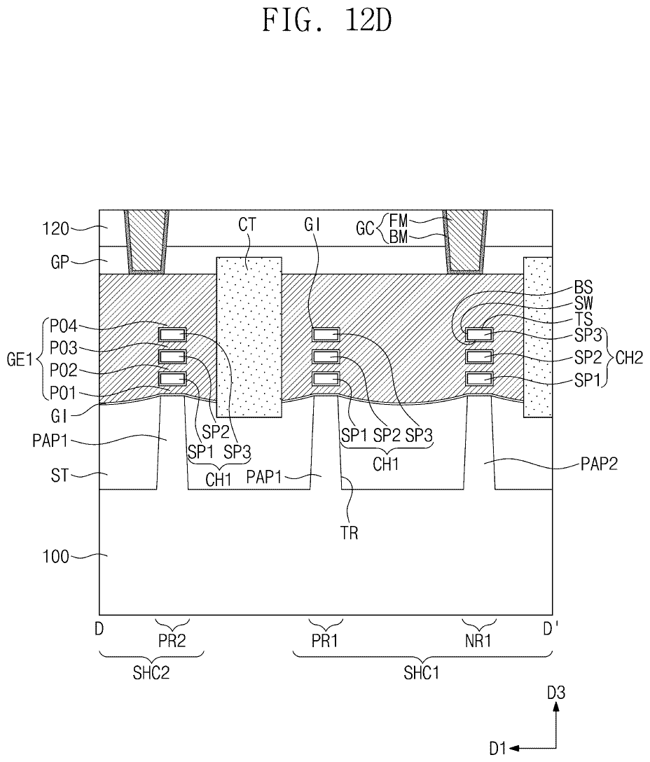

Referring to FIGS. 12A to 12D, the gate insulating layer GI may be conformally formed on the first to third semiconductor patterns SP1, SP2, and SP3 exposed. The gate electrode GE may be formed on the gate insulating layer GI. The gate electrode GE may include the first to third inner electrodes PO1, PO2, and PO3, which are respectively formed in the first to third inner regions IRG1, IRG2, and IRG3, and the outer electrode PO4, which is formed in the outer region ORG.

The gate electrode GE may be vertically recessed to have a reduced height. Upper portions of first and second gate cutting patterns among the gate cutting patterns CT may be slightly recessed, during the recessing of the gate electrode GE. The gate capping pattern GP may be formed on the recessed gate electrode GE.

The second interlayer insulating layer 120 may be formed on the first interlayer insulating layer 110. The second interlayer insulating layer 120 may include a silicon oxide layer. The gate contact GC may be formed to penetrate the second interlayer insulating layer 120 and the gate capping pattern GP and may be electrically connected to the gate electrode GE.

The formation of the gate contacts GC may include forming the barrier pattern BM and forming the conductive pattern FM on the barrier pattern BM. The barrier pattern BM may be conformally formed and may include a metal layer and a metal nitride layer. The conductive pattern FM may be formed of or include a low resistance metallic material.

Referring back to FIG. 4 and FIGS. 5A to 5D, the third interlayer insulating layer 130 may be formed on the gate contacts GC. The first metal layer M1 may be formed in the third interlayer insulating layer 130. The first metal layer M1 may include the first interconnection line M1_I, which is electrically connected to at least one of the gate contacts GC. The fourth interlayer insulating layer 140 may be formed on the third interlayer insulating layer 130. The second metal layer M2 may be formed in the fourth interlayer insulating layer 140.

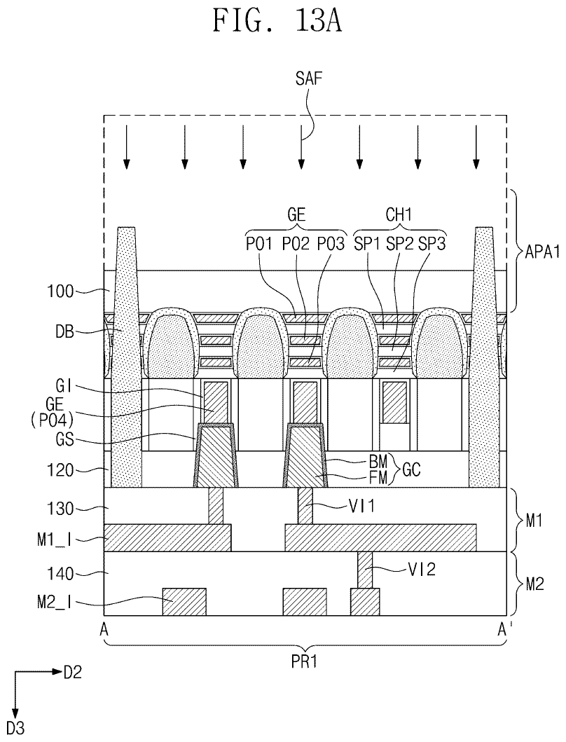

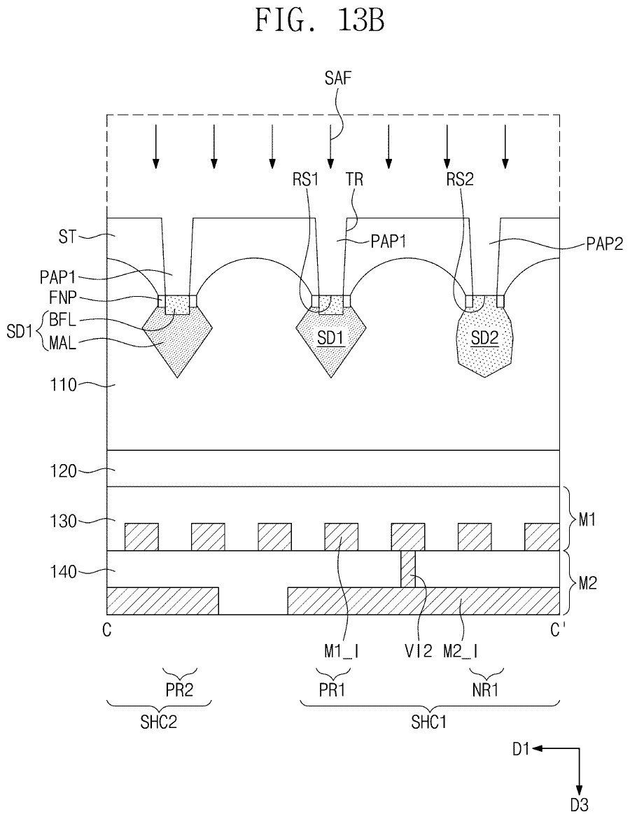

Referring to FIGS. 13A and 13B, after a BEOL process, the substrate 100 may be inverted such that the bottom surface of the substrate 100 is exposed to the outside. The exposed portion of the substrate 100 may be removed. In an embodiment, a planarization process SAF may be performed on the bottom surface of the substrate 100 to reduce a thickness of the substrate 100. The etching process may be performed to expose a bottom surface of the division structure DB. The first and second preliminary active patterns PAP1 and PAP2 on the substrate 100 may form the first and second active patterns AP1 and AP2, respectively.

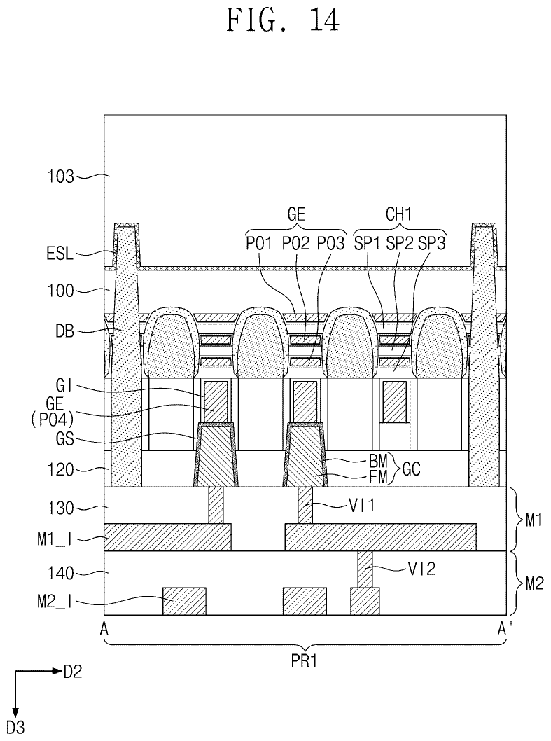

Referring to FIG. 14, the etch stop layer ESL may be conformally formed on the bottom surface of the substrate 100 etched. The etch stop layer ESL may be formed of or include a material different from the substrate 100. The etch stop layer ESL may cover bottom and side surfaces of the division structure DB, but inventive concepts are not limited to this example. The etch stop layer ESL may have a multi-layered structure.

A first mold layer 103 may be formed on the etch stop layer ESL. The first mold layer 103 may include at least one of an amorphous silicon layer, an amorphous carbon layer, a spin-on-hardmask (SOH) layer, and a spin-on-carbon (SOC) layer.

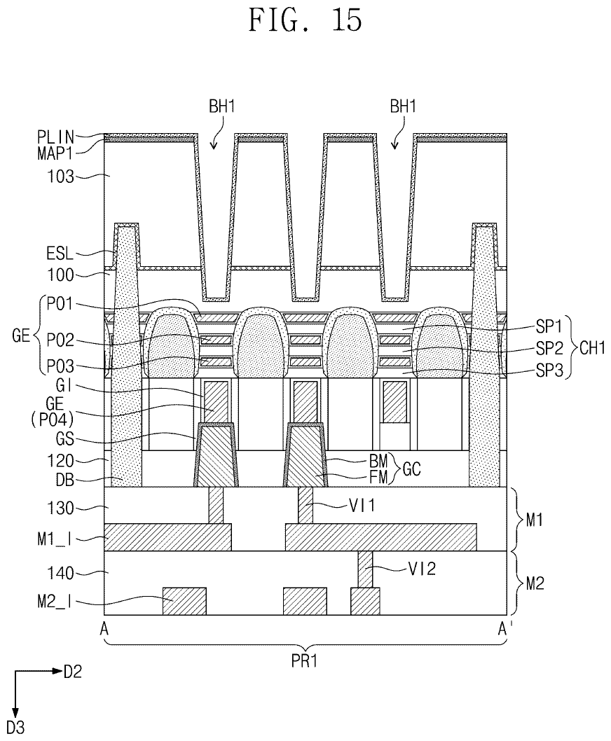

Referring to FIG. 15, first mask patterns MAP1 may be formed on the first mold layer 103. An etching process using the first mask patterns MAP1 as a mask may be performed on the first mold layer 103. The etching process may be a dry etching process. A first backside hole BH1 may be formed by etching the first mold layer 103, the etch stop layer ESL, and the substrate 100 through the etching process.

The first backside hole BH1 may not penetrate the substrate 100. For example, the first backside hole BH1 may not expose the gate insulating layer GI. A width of the first backside hole BH1 may decrease as a distance from a bottom surface of the first mold layer 103 increases. A bottom surface of the first backside hole BH1 may be spaced apart from a bottom surface of the gate electrode GE or a bottom surface of the gate insulating layer GI by a distance of 1 nm to 5 nm.

A first preliminary liner PLIN may be conformally formed on the substrate 100. The first preliminary liner PLIN may cover an inner surface of the first backside hole BH1. The first preliminary liner PLIN may be provided to cover top surfaces of the first mask patterns MAP1. The first preliminary liner PLIN may include a material having an etch selectivity with respect to the substrate 100. For example, the first preliminary liner PLIN may be formed of or include at least one of silicon-based insulating materials (e.g., SiO, SiN, SiOC, or SiOCN).

Referring to FIG. 16, an etching process may be performed on a top surface of the substrate 100 to remove a portion of the first preliminary liner PLIN. The etching process may be a break-through (BT) process. The first preliminary liner PLIN on the first mask patterns MAP1 may be removed by the etching process. In an embodiment, the etching process may be performed to remove the first preliminary liner PLIN covering the bottom surface of the first backside hole BH1 and to expose the substrate 100. The etching process may be performed to remove the first preliminary liner PLIN covering an upper portion of an inner surface of the first backside hole BH1.

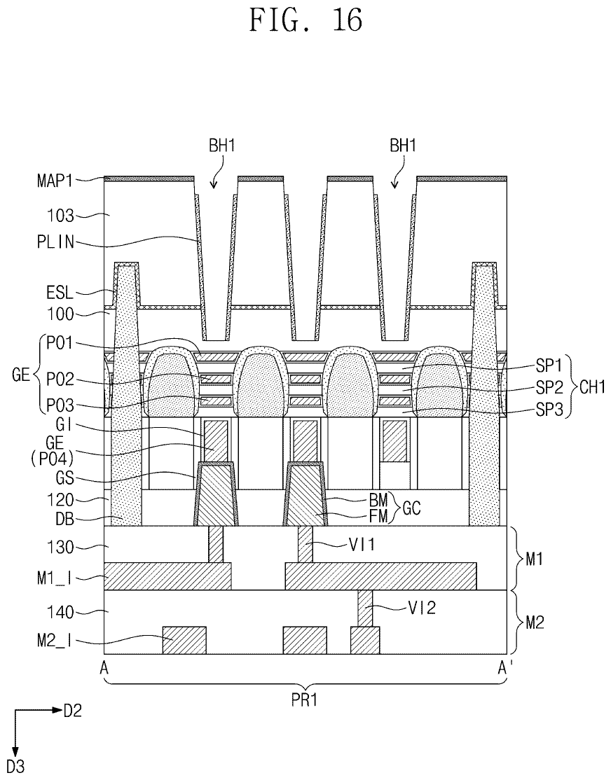

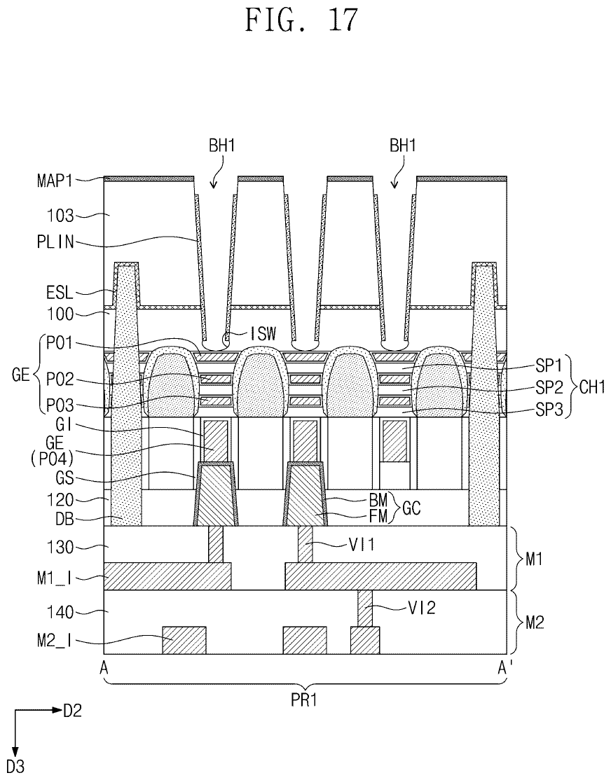

Referring to FIG. 17, an etching process may be performed using the first mask patterns MAP1 as a mask. The etching process may be a wet etching process. In an embodiment, the etching process may be performed to etch the substrate 100 exposed by the first backside hole BH1 and to expose at least a portion of the gate insulating layer GI. The etched substrate 100 may have a first inner side surface ISW. The first inner side surface ISW may have an ellipse profile. Alternatively, the first inner side surface ISW may have a polygonal shape. For example, the first inner sidewall ISW may have a sigma profile.

The first backside hole BH1 may be formed to be deeper than the first preliminary liner PLIN. Since the etching process is performed in a wet manner, it may be possible to etch the substrate 100, without damage of the gate insulating layer GI or the gate electrode GE. The first preliminary liner PLIN may not be etched by the etching process. The etching process may include a wet etching process that is performed using etching solution capable of selectively etching the substrate 100.

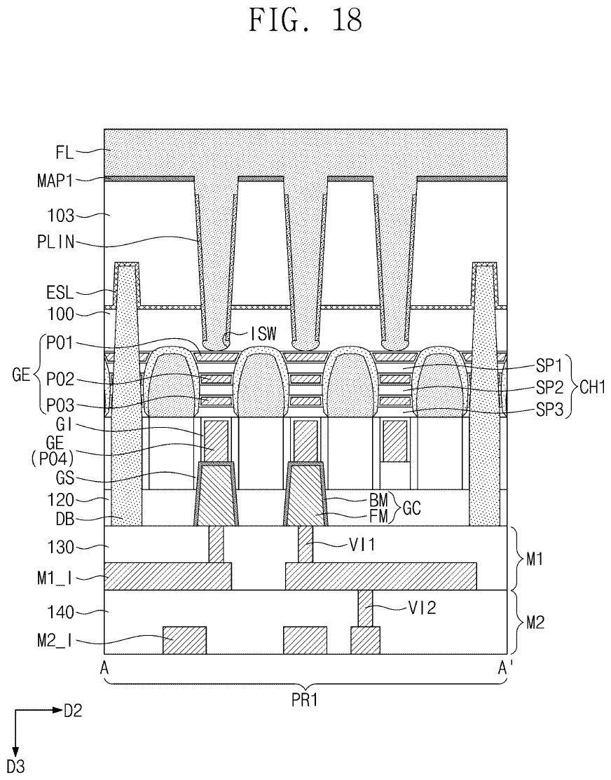

Referring to FIG. 18, a filling layer FL may be formed on the substrate 100. The filling layer FL may be formed to fill the first backside hole BH1. The filling layer FL may include an insulating material. In an embodiment, the filling layer FL may include a silicon oxide layer, but inventive concepts are not limited to this example.

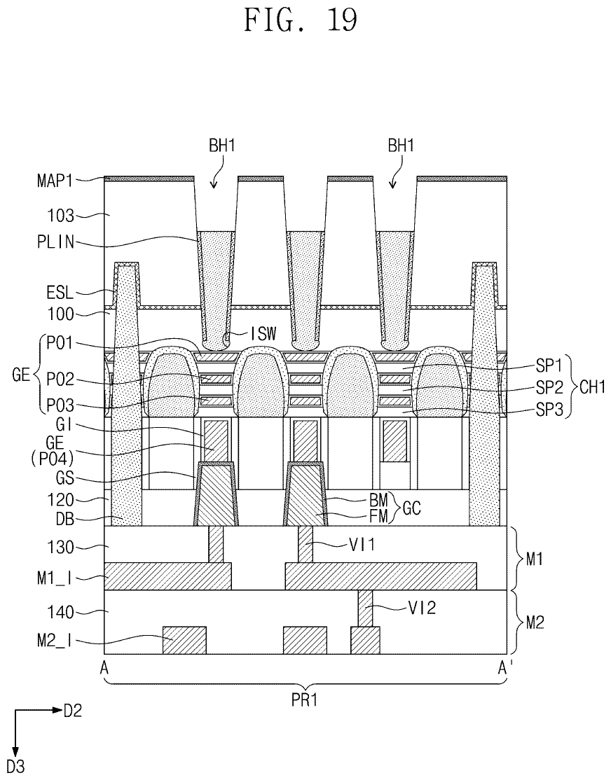

Referring to FIG. 19, an etch-back process may be performed on the substrate 100 to etch a portion of the filling layer FL. Thus, heights of the filling layer FL and the first preliminary liner PLIN in the first backside hole BH1 may be reduced. A top surface of the filling layer FL and a top surface of the first preliminary liner PLIN may be located at a level that is lower than a level of a top surface of the first mold layer 103.

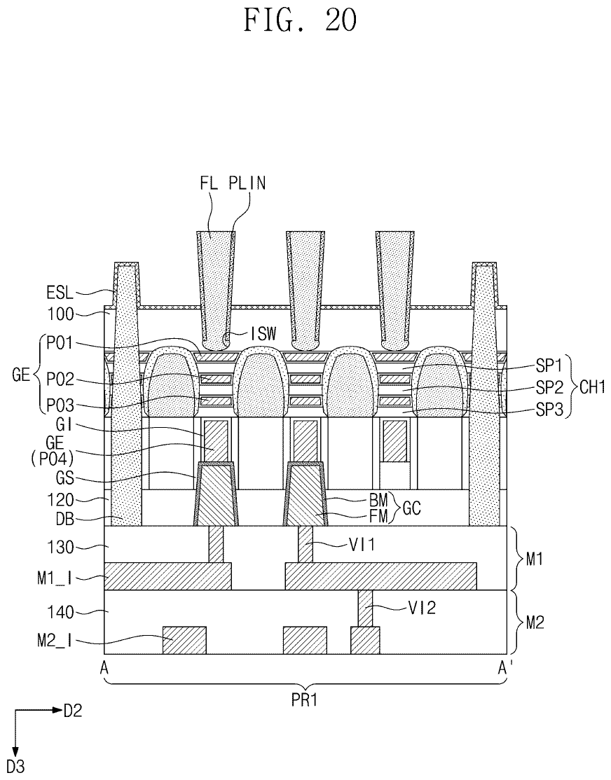

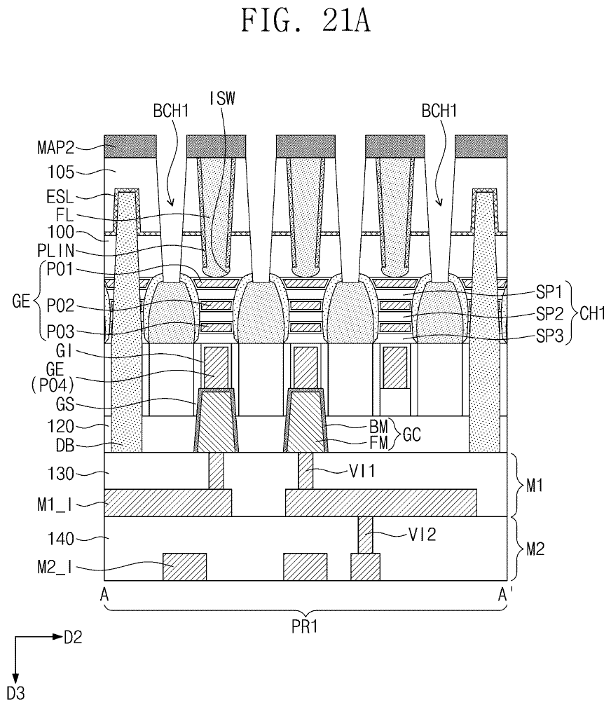

Referring to FIG. 20, a cleaning process may be performed to fully remove the first mold layer 103. The etch stop layer ESL, the filling layer FL, and the first preliminary liner PLIN may not be removed.

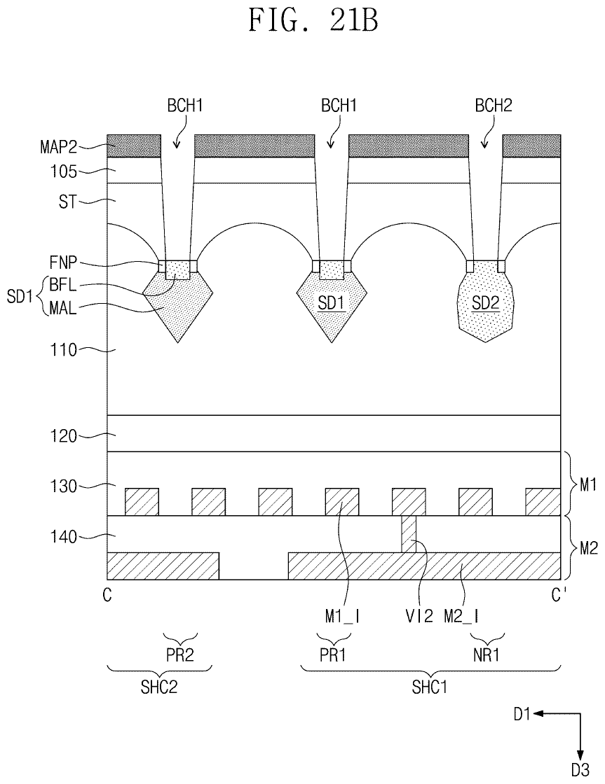

Referring to FIGS. 21A and 21B, a second mold layer 105 may be formed on the substrate 100. The second mold layer 105 may include an insulating material. For example, the second mold layer 105 may include at least one of an amorphous silicon layer, an amorphous carbon layer, a spin-on-hardmask (SOH) layer, and a spin-on-carbon (SOC) layer.

Second mask patterns MAP2 may be formed on the second mold layer 105. An etching process using the second mask patterns MAP2 as a mask may be performed to etch the second mold layer 105, the etch stop layer ESL, and the substrate 100 and to form a first backside contact hole BCH1. Lower portions of the first source/drain patterns SD1 may be exposed by the first backside contact hole BCH1.

Referring back to FIG. 4 and FIGS. 5A to 5D, a metallic material may be formed to fill the first backside contact hole BCH1. Thereafter, the second mold layer 105 and the second mask pattern MAP2 may be removed. In this case, the height of the filling layer FL and the first preliminary liner PLIN may be reduced to form the filler structure PLS. A metallic material may be formed on the etch stop layer ESL to form the first and second backside contacts BCA1 and BCA2. The first and second backside contacts BCA1 and BCA2, which are adjacent to each other, may be spaced apart from each other, with the filler structure PLS interposed therebetween.

The lower power line VPR1-VPR3 may be formed on the substrate 100. The lower power line VPR1-VPR3 may be connected to at least one of first and second backside contacts BSC1 and BSC2. The power delivery network layer PDN may be formed on the lower power line VPR1-VPR3. The power delivery network layer PDN may be formed to apply a source or drain voltage to the lower power lines VPR1 to VPR3.

In the fabrication method according to an embodiment of inventive concepts, the filler structure PLS may be formed by performing two etching processes. The filler structure PLS may be formed by performing not only a dry etching process but also a wet etching process. Since the wet etching process is performed, it may be possible to limit and/or prevent the gate insulating layer GI from being damaged when the substrate 100 is etched to form the first inner side surface ISW. Thus, it may be possible to protect both the gate insulating layer GI and the gate electrode GE. As a result, the reliability and electrical characteristics of the semiconductor device may be improved.

According to an embodiment of inventive concepts, a filler structure may be provided between backside contacts to be in contact with a gate insulating layer. The filler structure may be used to electrically separate adjacent ones of the backside contacts from each other. The filler structure may include a filling pattern and a liner, and here, the liner may cover side surfaces of a filler portion of the filling pattern. However, a contact portion of the filling pattern may be in direct contact with the substrate, without the liner interposed therebetween.

In a fabrication method according to an embodiment of inventive concepts, the filler structure may be formed by performing two etching processes. A wet etching process may be performed to limit and/or prevent a gate electrode and a gate insulating layer from being damaged. As a result, the reliability and electrical characteristics of the semiconductor device may be improved.

While example embodiments of inventive concepts have been particularly shown and described, it will be understood by one of ordinary skill in the art that variations in form and detail may be made therein without departing from the spirit and scope of the attached claims.

What is claimed is:

1. A semiconductor device, comprising:
a substrate including an active pattern;
a lower power line in a lower portion of the substrate;
a channel pattern on the active pattern, the channel pattern including a plurality of semiconductor patterns, the plurality of semiconductor patterns being stacked and spaced apart from each other, and a lowermost level of the plurality of semiconductor patterns including a first semiconductor pattern;
a gate electrode crossing the active pattern, the gate electrode including a first inner gate electrode between the active pattern and the first semiconductor pattern;
source/drain patterns on the substrate;
backside contacts connecting the lower power line to the source/drain patterns; and
a filler structure between adjacent backside contacts among the backside contacts, wherein
the filler structure includes a filling pattern and a liner,
the filling pattern includes a filler portion and a contact portion on the filler portion,
the liner covers opposite side surfaces of the filler portion, and
the contact portion is in direct contact with the substrate.

2. The semiconductor device of claim 1, further comprising:
a gate insulating layer between the first inner gate electrode and the substrate, wherein
a portion of the contact portion is in direct contact with the gate insulating layer.

3. The semiconductor device of claim 1, wherein a topmost portion of the liner is lower than a topmost portion of the contact portion.

4. The semiconductor device of claim 1, wherein a height difference between a level of a top surface of the liner and a level of a top surface of the contact portion ranges from 1 nm to 5 nm.

5. The semiconductor device of claim 1, further comprising:
an etch stop layer between the substrate and the backside contacts.

6. The semiconductor device of claim 1, wherein a material of the liner is different than a material of the filler portion and a material of the contact portion.

7. The semiconductor device of claim 1, wherein a material of the liner has an etch selectivity with respect to a material of the substrate.

8. The semiconductor device of claim 1, further comprising:
a power delivery network layer below the substrate,
wherein the power delivery network layer is configured to apply a source voltage or a drain voltage to the lower power line.

9. The semiconductor device of claim 1, wherein the liner is between the filler portion and the substrate and between the filler portion and the backside contacts.

10. The semiconductor device of claim 1, wherein
as a distance from a bottom surface of the filling pattern increases in a vertical direction, a width of the filling pattern decreases and then increases at a boundary between the filler portion and the contact portion.

11. A semiconductor device, comprising:
a substrate including an active pattern;
a lower power line in a lower portion of the substrate;
a channel pattern on the active pattern, the channel pattern including a plurality of semiconductor patterns, the plurality of semiconductor patterns being stacked and spaced apart from each other, and a lowermost level of the plurality of semiconductor patterns including a first semiconductor pattern;
a gate electrode crossing the active pattern, the gate electrode including a first inner gate electrode between the active pattern and the first semiconductor pattern;
source/drain patterns on the substrate;
backside contacts connecting the lower power line to the source/drain patterns; and
a filler structure between adjacent backside contacts among the backside contacts, wherein
the filler structure includes a filling pattern and a liner,
the filling pattern includes a filler portion and a contact portion on the filler portion,
the liner covers opposite side surfaces of the filler portion, and
a topmost portion of the liner is lower than a topmost portion of the contact portion.

12. The semiconductor device of claim 11, wherein a height difference between a level of a top surface of the liner and a level of a top surface of the contact portion ranges from 1 nm to 5 nm.

13. The semiconductor device of claim 11, further comprising:
a gate insulating layer between the first inner gate electrode and the substrate, wherein
at least a portion of the contact portion is in direct contact with the gate insulating layer.

14. The semiconductor device of claim 11, wherein a material of the liner has an etch selectivity with respect to a material of the substrate.

15. The semiconductor device of claim 11, further comprising:
an etch stop layer between the substrate and the backside contacts.

16. A semiconductor device, comprising:
a substrate including an active pattern;
channel patterns on the active pattern, the channel patterns including a plurality of semiconductor patterns, the plurality of semiconductor patterns being stacked and spaced apart from each other, the plurality of semiconductor patterns including a first semiconductor pattern;
source/drain patterns connected to the channel patterns;
a gate electrode on the channel patterns, the gate electrode including a first inner gate electrode between the active pattern and first semiconductor pattern;
a gate insulating layer between the gate electrode and the channel patterns;
a gate spacer on a side surface of the gate electrode;
a gate capping pattern on a top surface of the gate electrode;
an interlayer insulating layer covering the source/drain pattern and the gate capping pattern;
a gate contact penetrating the interlayer insulating layer and the gate capping pattern, the gate contact being electrically connected to the gate electrode;
a first metal layer on the interlayer insulating layer, the first metal layer include a first interconnection line electrically connected to the gate contact;
a lower power line in a lower portion of the substrate;
backside contacts penetrating the substrate and electrically connecting the lower power line to the source/drain pattern; and
a filler structure between adjacent backside contacts among the backside contacts, wherein
the filler structure includes a filling pattern and a liner,
the filling pattern includes a filler portion and a contact portion on the filler portion,
the liner covers opposite side surfaces of the filler portion, and
as a distance from a bottom surface of the filling pattern increases in a vertical direction, a width of the filling pattern decreases and then increases at a boundary between the filler portion and the contact portion.

17. The semiconductor device of claim 16, wherein
the gate electrode comprises a first inner gate electrode between the active pattern and first semiconductor pattern,
the gate insulating layer is between the first inner gate electrode and the substrate, and
at least a portion of the contact portion is in direct contact with the gate insulating layer.

18. The semiconductor device of claim 16, wherein the contact portion is in direct contact with the substrate.

19. The semiconductor device of claim 16, wherein a height difference between a level of a top surface of the liner and a level of a top surface of the contact portion ranges from 1 nm to 5 nm.

20. The semiconductor device of claim 16, wherein a material of the liner is different from a material of the filler portion and a material of the contact portion.
